(19) United States
(12) Patent Application Publication
(10) Pub. No.: US 2026/0242926 A1
(43) Pub. Date: Aug. 20, 2026

(54) OPTICAL THIN FILM, METHOD FOR PRODUCING THE SAME, OPTICAL ELEMENT, AND OPTICAL APPARATUS

(71) Applicant: Tamron Co., Ltd., Saitama (JP)

(72) Inventors: Erika Katayama, Saitama (JP); Minoru Shibuya, Saitama (JP)

(73) Assignee: Tamron Co., Ltd., Saitama (JP)

(21) Appl. No.: 19/445,670

(22) Filed: Jan. 12, 2026

(30) Foreign Application Priority Data
Feb. 14, 2025 (JP) 2025-022621

(51) Int. Cl. C23C 14/08; B32B 7/12; B32B 27/06; C23C 14/10

(52) U.S. Cl. CPC C23C 14/083; B32B 7/12; B32B 27/06; C23C 14/10; B32B 2307/204; B32B 2307/7376; B32B 2551/00

(57) ABSTRACT

An optical thin film of the present disclosure includes one or more MO mixed layers in which an organometallic compound is mixed in a layer formed by physical vapor deposition of magnesium fluoride.

### CROSS-REFERENCE TO RELATED APPLICATIONS

This application is based on and claims the benefit of priority from Japanese Patent Application No. 2025-022621, filed on Feb. 14, 2025, the entire contents of which are incorporated herein by reference.

### BACKGROUND OF THE INVENTION

### Technical Field

The present invention relates to an optical thin film, a method for producing the same, an optical element, and an optical apparatus.

### Related Art

In recent years, along with weight reduction and cost reduction of general-purpose lenses such as in-vehicle lenses and monitoring lenses, there is an active movement to replace glass lenses with plastic lenses. However, the linear expansion coefficients of the plastic and the inorganic thin film are different by about 10 times. Therefore, when an antireflection film that has been applied to a glass lens in the related art is applied to a plastic lens, there is a problem that the plastic substrate has a large elongation under a high-temperature environment due to a thermal expansion difference between the plastic substrate and the antireflection film, and the antireflection film cannot follow the elongation of the substrate and is easily broken (cracks are generated).

As a technique for suppressing the occurrence of cracks in an optical thin film coating such a resin lens, there is known a technique for defining a range of compressive stress or Young's modulus of each layer in a multilayer film including a stacked structure of a layer formed using a high refractive index dielectric material and a layer formed using a low refractive index dielectric material (see, for example, JP 2021-21893 A).

As the technique, there is also known a technique of suppressing the occurrence of cracks by limiting the ratio of the film thickness of the layer of the low refractive index dielectric material closest to the substrate side among the layers of the low refractive index dielectric material to the total film thickness of the multilayer film (see, for example, JP 2019-144552 A and JP 2015-129129 A).

As the technique, a technique is also known in which a substrate having heat resistance of 105° C. or higher is used, and the total film thickness and stress range of the multilayer film are limited to increase the heat resistance of the multilayer film (see, for example, JP 2019-66600 A).

However, such adjustment of the film stress is also limited, and when the film stress is adjusted in order to suppress the occurrence of cracks, the antireflection performance may be insufficient due to design restrictions.

In general, in order to make the antireflection film low in reflection, a method of depositing a low refractive index substance on the outermost layer of a coat is known. Among them, magnesium fluoride (MgF₂) has a low refractive index as compared with other low refractive index substances such as SiO₂, and is widely used as an antireflection film material on a glass substrate.

However, MgF₂ usually has a strong tensile stress, and when used as a film material for a resin substrate, there is a problem that cracks occur under high temperature conditions, and it is difficult to use MgF₂ on the resin substrate. Therefore, in the method for controlling the film stress which is a conventional technique, there is almost no example of using MgF₂, and the film thickness is only adjusted using a material other than MgF₂.

In addition to the film stress, MgF₂ also has a problem that when a film is formed at a temperature of 200° C. or lower, the film becomes weak and the scratch resistance deteriorates. In general, when coating is applied to an optical resin substrate, it is necessary to form a film at a temperature equal to or lower than the glass transition point of the resin, and thus the film is formed at 200° C. or lower (actually 100° C. or lower in consideration of the shape change of the substrate). In this case, when MgF₂ is used as the outermost layer, scratch resistance cannot be secured, and the film cannot withstand practical use.

Due to these problems, it is difficult to use MgF₂ on a resin substrate, and a plastic lens having antireflection performance and heat resistance equivalent to those of a glass lens has not been put into practical use at present.

All of the above patent documents have a film design with enhanced heat resistance, but do not use MgF₂ (in JP 2021-21893 A, JP 2015-129129 A, and JP 2015-129129 A, MgF₂ is not mentioned at all, and in JP 2019-144552 A, there is no example using MgF₂). For this reason (this is because SiO₂ having a refractive index higher than that of MgF₂ or a mixed compound mainly containing SiO₂ is used as an optical outermost layer), there is a problem that the reflection band is narrow or the antireflection film has a high reflectance.

An object of one aspect of the present invention is to realize a new optical thin film that realizes exhibition of desired optical characteristics and suppression of occurrence of cracks.

### SUMMARY OF THE INVENTION

In order to solve the above problems, an optical thin film according to an aspect of the present invention includes one or more MO mixed layers in which an organometallic compound is mixed in a layer formed by physical vapor deposition of magnesium fluoride.

In order to solve the above problems, an optical element according to an aspect of the present invention includes a substrate and the optical thin film supported thereon.

In order to solve the above problems, an optical apparatus according to an aspect of the present invention includes the above optical element.

In order to solve the above problems, a manufacturing method of an optical thin film according to an aspect of the present invention includes forming a layer of a dielectric material on a substrate by physical vapor deposition in an atmosphere containing an organometallic compound and a reactive gas to form a mixed layer in which the organometallic compound is mixed in the layer of an oxide, an oxynitride, or a nitride of the dielectric material, in which the forming of the mixed layer includes forming an MO mixed layer in which the organometallic compound is mixed in a layer by physical vapor deposition of magnesium fluoride using magnesium fluoride as the dielectric material.

According to one aspect of the present invention, it is possible to realize a new optical thin film that realizes exhibition of desired optical characteristics and suppression of occurrence of cracks.

### BRIEF DESCRIPTION OF THE DRAWINGS

FIG. 1 is a diagram schematically illustrating an exemplary configuration of an optical thin film according to an embodiment of the present invention;

FIG. 2 is a diagram schematically illustrating another exemplary configuration of the optical thin film according to an embodiment of the present invention;

FIG. 3 is a diagram schematically illustrating a configuration of a first example in a manufacturing apparatus of an optical thin film according to an embodiment of the present invention;

FIG. 4 is a diagram schematically illustrating a configuration of a second example in the manufacturing apparatus of the optical thin film according to an embodiment of the present invention;

FIG. 5 is a diagram schematically illustrating a configuration of a third example in the manufacturing apparatus of the optical thin film according to an embodiment of the present invention;

FIG. 6 is a diagram schematically illustrating a configuration of a fourth example in the manufacturing apparatus of the optical thin film according to an embodiment of the present invention;

FIG. 7 is a diagram schematically illustrating a configuration of a fifth example in the manufacturing apparatus of the optical thin film according to an embodiment of the present invention;

FIG. 8 is a graph illustrating element ratios of an optical thin film 1 and an optical thin film 2 in an example of the present invention;

FIG. 9 is a graph of spectral reflectance (calculated value) at a wavelength of 350 to 750 nm of an optical thin film 5 in a fifth example of the present invention;

FIG. 10 is a graph of spectral reflectance (calculated value) at a wavelength of 350 to 750 nm of an optical thin film 6 in a sixth example of the present invention;

FIG. 11 is a graph of spectral reflectance (calculated value) at a wavelength of 350 to 750 nm of an optical thin film 7 in a seventh example of the present invention;

FIG. 12 is a graph of spectral reflectance (calculated value) at a wavelength of 350 to 750 nm of an optical thin film 8 in an eighth example of the present invention;

FIG. 13 is a graph of spectral reflectance (calculated value) at a wavelength of 350 to 750 nm of an optical thin film 9 in a ninth example of the present invention;

FIG. 14 is a graph of spectral reflectance (calculated value) at a wavelength of 350 to 750 nm of an optical thin film 10 in a tenth example of the present invention;

FIG. 15 is a graph of spectral reflectance (calculated value) at a wavelength of 350 to 750 nm of an optical thin film 11 in an eleventh example of the present invention;

FIG. 16 is a graph of spectral reflectance (calculated value) at a wavelength of 350 to 750 nm of an optical thin film 12 in a twelfth example of the present invention;

FIG. 17 is a graph of spectral reflectance (calculated value) at a wavelength of 350 to 750 nm of an optical thin film 13 in a thirteenth example of the present invention;

FIG. 18 is a graph of spectral reflectance (calculated value) at a wavelength of 350 to 950 nm of an optical thin film 14 in a fourteenth example of the present invention;

FIG. 19 is a graph of spectral reflectance (calculated value) at a wavelength of 350 to 750 nm of an optical thin film C2 in a second comparative example of the present invention;

FIG. 20 is a graph of spectral reflectance (calculated value) at a wavelength of 350 to 750 nm of an optical thin film C3 in a third comparative example of the present invention; and

FIG. 21 is a graph of spectral reflectance (calculated value) at a wavelength of 350 to 750 nm of an optical thin film C4 in a fourth comparative example of the present invention.

### DESCRIPTION OF THE EMBODIMENTS

### [Optical Thin Film]

The optical thin film according to the embodiment of the present invention includes one or more MO mixed layers. The optical thin film may be a monolayer film including only the MO mixed layer, or may be a multilayer film including the MO mixed layer and another layer. The optical thin film as a monolayer film of the MO mixed layer is suitable for, for example, a surface protective layer of an optical element.

The MO mixed layer is a layer in which an organometallic compound is mixed in a layer formed by physical vapor deposition (PVD) of magnesium fluoride. The MO mixed layer contains magnesium fluoride (MgF₂) and an organometallic compound, and for example, when both compounds form a sea-island structure in the MO mixed layer, one of the sea-islands is magnesium fluoride and the others are organometallic compounds.

In addition to the organometallic compound, the MO mixed layer may contain one or more compounds including an oxidation reactant thereof, an oxynitride thereof, and a nitride thereof. Organometallic compounds and compounds derived from these organometallic compounds are also referred to as “organometallic material compounds”. The organometallic material compound may be an accessory component constituting the mixed layer or a trace component in the mixed layer.

The organometallic compound may be any material that can be formed into a film by chemical vapor deposition (chemical deposition, CVD). Examples of the compound include an organic compound containing one or more elements selected from the group consisting of Si, Al, Ti, Hf, and Mg. These organometallic compounds are preferable from the viewpoint of achieving desired antireflection characteristics in an optical thin film that is a multilayer film. More specifically, examples of the organometallic material compound include organic SiO₂, organic TiO₂, organic Al₂O₃, organic Hf₂O₃, and organic MgF₂. In one MO mixed layer, one or more kinds of organometallic material compounds may be used.

The content of the organometallic material compound in the MO mixed layer can be appropriately determined according to film properties such as a desired compressive film stress in the optical thin film and optical characteristics such as reflectance according to the application of the optical thin film. The content of magnesium fluoride in the MO mixed layer is represented by the amount of magnesium (Mg) which is a metal element contained in magnesium fluoride, and the content of the organometallic material compound in the MO mixed layer is represented by the content of a metal element (Si or the like) contained in the organometallic material compound. The content of the organometallic material compound in the MO mixed layer may be, for example, 1 to 90 mass %.

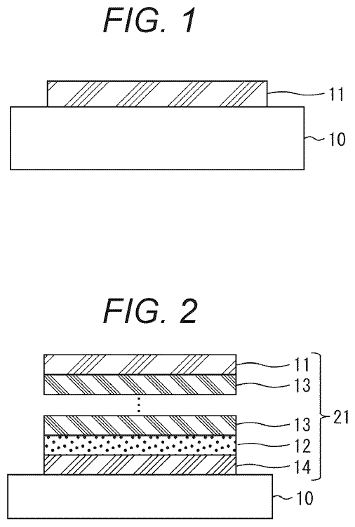

FIG. 1 schematically illustrates an optical thin film of the present embodiment which is a monolayer film. As described above, the optical thin film of the present embodiment can be a MO mixed layer 11 formed on a substrate 10. The substrate 10 is a plate-like substrate, and is a carrier that supports an optical thin film 1 on the surface thereof. The substrate 10 is, for example, a resin optical element such as a resin lens.

The MO mixed layer 11 is a layer in which an organometallic material compound is mixed by CVD in a PVD layer of magnesium fluoride. Although the PVD layer of magnesium fluoride has strong tensile stress, the layer by CVD of organometallic material compound has strong compressive stress, and as a result, the MO mixed layer 11 has optical characteristics of the PVD layer of magnesium fluoride and the tensile stress of the layer is reduced. Therefore, the MO mixed layer 11 has a sufficiently low tensile stress (or compressive stress) and sufficiently follows the thermal expansion of the substrate 10 even at a high temperature, and thus the occurrence of cracks in the MO mixed layer 11 (optical thin film) is prevented.

As described above, the optical thin film may include only the MO mixed layer, but may be a multilayer film in which the MO mixed layer and other layers overlap. Such an optical thin film in the present embodiment is a multilayer film formed by stacking two or more dielectric layers having different refractive indexes, and may include the above-described MO mixed layer as at least one layer of the dielectric layers. It is preferable that the optical thin film is a multilayer film as described above from the viewpoint of enhancing optical characteristics such as antireflection characteristics in the optical thin film.

The number and positions of the MO mixed layers in the lamination direction of the multilayer film are not limited, and for example, the MO mixed layer may be a surface layer in the multilayer film, may be in a bottom layer (layer closest to the substrate), or may be an intermediate layer located therebetween.

For example, the optical thin film which is a multilayer film in the present embodiment may include a configuration in which a first layer including a configuration of a PVD layer of a first dielectric material and a second layer including a configuration of a PVD layer of a second dielectric material and having a refractive index different from that of the first layer are alternately overlapped. At least one of the first layer and the second layer may be an MO mixed layer, or the multilayer film may further include an MO mixed layer separately from the first layer and the second layer.

The optical thin film which is a multilayer film preferably includes an MO mixed layer as an optical outermost layer from the viewpoint of suppressing damage to the optical functional layer. The “optically outermost layer” means a layer located on the outermost surface side (for example, the side opposite to the substrate) among the optically functional layers in the multilayer film. The “optically functional layer” is, for example, a layer designed and formed to exhibit a desired refractive index in a multilayer film, and is the above-described MO mixed layer, and may be the first layer or the second layer.

Various functional films designed and formed to exhibit other functions that do not substantially function optically, such as an adhesive film, a protective film, an antifouling film, and a conductive film described later, are not included in the “optically functional layer”. However, the optical thin film may further include a layer other than the “optically functional layer” as long as the effect of the present embodiment can be obtained.

The optical thin film of the multilayer film including the MO mixed layer is suitable as an antireflection film, and is suitable from the viewpoint of enhancing the antireflection characteristics in the antireflection film and the viewpoint of improving the durability of the antireflection film (suppressing the occurrence of cracks).

The first dielectric material and the second dielectric material can be appropriately determined in a range in which the optical characteristics of the first layer and the second layer are substantially different, and may be the same or different. Such a dielectric material is a material that constitutes the layer configuration described above, and may be a main component in the first layer or the second layer. The dielectric material is a material that can form a layer by, for example, PVD, and more specifically, can be a material constituting each layer in a conventional multi-layered antireflection film. The dielectric layer made of such a material is not particularly limited, but may be a layer made of an oxide, an oxynitride, or a nitride of a dielectric material containing one or more elements selected from the group consisting of Ti, Zr, Ta, La, Nb, Hf, Al, Si, Pr, Y, and Ce by physical vapor deposition of the dielectric material. The dielectric layer preferably has such a configuration from the viewpoint of achieving desired optical characteristics of the optical thin film, such as antireflection characteristics when formed into a multilayer film.

Further, the dielectric layer in the multilayer film may be a mixed layer (DO mixed layer) in which an organometallic compound is mixed in the layer of the dielectric material as in the MO mixed layer. That is, the dielectric layer in the multilayer film may include a DO mixed layer in which an organometallic compound is mixed in a layer of an oxide, an oxynitride, or a nitride of a dielectric material containing one or more elements selected from the group consisting of Ti, Zr, Ta, La, Nb, Hf, Al, Si, Pr, Y, and Ce by physical vapor deposition. The inclusion of the DO mixed layer in the multilayer film is preferable from the viewpoint of appropriately adjusting the film stress to suppress the occurrence of cracks in addition to the viewpoint of enhancing the antireflection characteristics in the optical thin film because the film stress of the alternately stacked structure in the multilayer film can be adjusted to be closer to the compressive stress (low tensile stress or compressive stress).

Examples of the dielectric material include TiO₂, ZrO₂, ZrO₂+TiO₂, La₂O₃, La₂O₃+TiO₂, Nb₂O₅, Hf₂O₃, Al₂O₃, SiO₂, Pr₂O₃, SiOₓN_{y}, and CeO₂. The “+” represents a mixture or a compound thereof. As described above, in one mixed layer, the dielectric material may be one or more of the exemplified materials.

It is preferable that the dielectric material contains Ti and the first layer or the second layer is a PVD layer of titanium from the viewpoint of realizing desired antireflection characteristics in the optical thin film of this embodiment.

As described above, one of the first layer and the second layer in the multilayer film may be an MO mixed layer or a DO mixed layer, and both may be separate MO mixed layers or DO mixed layers. In addition, one or both of the first layer and the second layer in the multilayer film may be a PVD layer of a dielectric material. For example, the optical thin film in the form of a multilayer film according to the present embodiment may have a configuration in which two or more kinds of mixed layers are alternately overlapped, or may have a configuration in which the mixed layer and a PVD layer of a dielectric material are alternately overlapped.

FIG. 2 schematically illustrates the optical thin film of the present embodiment which is a multilayer film. An optical thin film 21 is formed on the substrate 10 and has a stacked structure of a plurality of layers. The optical thin film 21 has an adhesion layer 14, an alternately stacked structure of a low refractive index layer 12 and a high refractive index layer 13, and an MO mixed layer 11 in order from the substrate 10 side.

The adhesion layer 14 is a layer made of, for example, an organometallic material compound. The adhesion layer 14 is formed by CVD of an organometallic compound, and has a compressive stress corresponding to the kind of the organometallic material compound. When the substrate 10 is made of resin, the adhesion layer 14 has good adhesion to both the substrate 10 and the low refractive index layer 12 or the high refractive index layer 13.

The low refractive index layer 12 is a layer containing a dielectric material exhibiting a refractive index lower than that of the film made of the dielectric material contained in the high refractive index layer 13, and has a film stress corresponding to the type of the dielectric material contained in the film. For example, the low refractive index layer 12 may be a film made of PVD of SiO₂, and in this case, the low refractive index layer 12 has compressive stress. The low refractive index layer 12 may be a PVD layer of SiO₂ or a DO mixed layer containing SiO₂.

The high refractive index layer 13 is a layer containing a dielectric material exhibiting a higher refractive index than a film made of a dielectric material contained in the low refractive index layer 12, and has a film stress corresponding to a type of the dielectric material contained in the film. For example, the high refractive index layer 13 may be a film formed by PVD of TiO₂ or a DO mixed layer containing TiO₂.

The optical thin film 21 exhibits optical characteristics (antireflection characteristics) by the alternately stacked structure of the low refractive index layer 12 and the high refractive index layer 13 and the MO mixed layer 11 located on the surface thereof. In addition, the optical thin film 21 has a specific film stress exhibited by three layers of the adhesion layer 14, the alternately stacked structure, and the MO mixed layer 11. The film stress of the optical thin film 21 can be substantially represented by the sum of the film stresses of the adhesion layer 14, the low refractive index layer 12, the high refractive index layer 13, and the MO mixed layer 11. The film stress of each layer can be determined according to the thickness of each layer.

When the tensile stress is positive and the compressive stress is negative, the optical thin film of the present embodiment preferably has a film stress of +200 to −1000 MPa from the viewpoint of suppressing occurrence of cracks due to a temperature change, particularly at a high temperature. From the above viewpoint, the film stress of the optical thin film can be appropriately determined on the basis of a requirement depending on the structure of the optical thin film or the application of the optical thin film. For example, the film stress of the optical thin film of the monolayer film is preferably +200 MPa or less from the above viewpoint. In addition, the film stress of the optical thin film of the multilayer film is preferably −100 to 1000 MPa from the above viewpoint. The film stress of the optical thin film tends to decrease as the amount of the organometallic material compound in the mixed layer increases, and in the multilayer film, the film stress tends to decrease as the film thickness of the film having compressive stress increases, and the film stress tends to increase as the film thickness of the film having tensile stress increases.

In addition, optical characteristics such as antireflection performance of the optical thin film of the present embodiment can also be appropriately determined according to the application of the optical thin film. For example, the optical thin film of the present embodiment preferably has a light reflectance of 0.5% or less in terms of light having a wavelength of 450 to 600 nm. It is preferable that the reflectance of light having a wavelength of 450 to 600 nm is 0.5% or less from the viewpoint of increasing the visible light transmittance, and thus it is suitable for applications such as video camera lenses.

Alternatively, the optical thin film of the present embodiment preferably has a light reflectance of 1.5% or less in terms of light having a wavelength of 400 to 850 nm. It is preferable that the reflectance of light having such a wavelength is 1.5% or less from the viewpoint of increasing the transmittance of visible to near-infrared light, and thus, it is suitable for applications of camera lenses for FA (industrial), monitoring, in-vehicle, and the like.

As described above, the optical thin film of the present embodiment can exhibit excellent antireflection performance and suppress the occurrence of cracks due to temperature changes, and thus the optical thin film is suitable for an antireflection film for a plastic lens mainly in a market requiring high environmental resistance such as an in-vehicle lens.

### [Manufacturing Method of Optical Thin Film]

The optical thin film of the present embodiment can be manufactured by a method including the mixed layer forming step of forming the mixed layer.

The mixed layer forming step is a step of forming a layer on the substrate by physical vapor deposition of a dielectric material in an atmosphere containing an organometallic compound and a reactive gas. By such a mixed layer forming step, a mixed layer in which an organometallic compound is mixed in a layer of an oxide, an oxynitride, or a nitride of a dielectric material can be formed. The mixed layer forming step can be performed by synchronizing CVD in which an organometallic material compound gas (precursor gas) or a reactive gas is introduced and reacted with a film forming step by PVD using magnesium fluoride or the above-described dielectric material as a raw material. In the mixed layer forming step, the organometallic material compound is mixed in the mixed layer by CVD of the organometallic compound under a film forming condition by PVD of magnesium fluoride or a dielectric material.

In the present embodiment, the mixed layer forming step includes a step of forming an MO mixed layer in which an organometallic compound is mixed in a layer by physical vapor deposition of magnesium fluoride using magnesium fluoride as a dielectric material. The MO mixed layer can be prepared in the same manner as other (known) dielectric material layers by using magnesium fluoride as the dielectric material in this manner.

The film forming step by PVD can be performed by irradiating the dielectric material with an electron beam from an electron gun, sputtering, resistance heating, or the like. In addition, it is preferable that the film forming step by PVD is performed under the condition of additionally generating plasma, ions, or heat in an auxiliary manner, from the viewpoint of appropriately setting the conditions of PVD of the dielectric material, and the generation of the organometallic material compound by CVD and the mixture thereof in the mixed layer. Furthermore, the film forming step by PVD may be performed in an atmosphere containing a reactive gas from the viewpoint of replenishing a specific element in the dielectric material in the mixed layer. The reactive gas may be appropriately selected according to the specific elements described above, and examples thereof include oxygen and nitrogen.

Various conditions of the film forming step by PVD for preparing the mixed layer are appropriately adjusted to conditions under which CVD of the organometallic compound occurs in parallel. Such conditions may be identified experimentally or estimated by calculation. The CVD of the organometallic compound can be suitably performed by reacting the organometallic compound and the reactive gas in the presence of plasma, ions, or heat supplementarily generated in the film forming step by PVD. In the present embodiment, it is preferable to perform the film forming step by PVD under the conditions of PVD in consideration of the conditions of CVD of such an organometallic compound from the viewpoint of appropriately adjusting the magnitude of the compressive stress of the optical thin film and the characteristics of the optical thin film.

The supply of the precursor gas in the film forming step by PVD may be performed at any timing in the film forming step, may be performed before or at the same time as the start of the film forming step, or may be performed at any timing after the start and before the end of the film forming step. The supply of the precursor gas may be stopped before or at the end of the film forming step. From the viewpoint of preparing a mixed layer having a stable composition and structure, it is preferable to perform the film forming step by PVD after preparing conditions that allow both film formation by PVD and CVD of an organometallic compound to be performed.

Both the conditions of the film forming step by PVD of the dielectric material and the conditions of CVD of the organometallic compound may be constant or varied. For example, by changing the film forming conditions by PVD, the supply amount of precursor gas, and the supply amount of reactive gas, the composition of the mixed layer can be changed gradually or stepwise in the thickness direction.

The substrate in the production method of the present embodiment may be an optical member coated with the optical thin film in the method for producing an optical thin film. The substrate may be an optical element or another member (such as a transparent film). The optical element will be described later.

The organometallic compound to be subjected to CVD is as described above, but a compound to be subjected to CVD is suitably selected as a precursor gas. The organometallic compound is appropriately selected alone or from compounds that can be converted into an organometallic material compound by reaction with a reactive gas. Examples of the metal element of the organometallic compound include Al, Ti, Ta, Si, Hf, and Mg. Examples of the organometallic compound containing such a metal element include trimethylaluminum (TMA, (CH₃)₃Al), tetrakis(dimethylamino) titanium (TDMAT, Ti[N(CH₃)₂]₄), tetraethyl orthosilicate (TEOS, Si(OC₂H₅)₄), trimethylsilane, (SiH(CH₃)₃), hexamethyldisiloxane (HMDSO, (CH₃)₃SiOSi(CH₃)₃), decamethyltetrasiloxane (C₁₀H₃₀O₃Si₄), hexamethylcyclotrisiloxane (C₆H₁₈O₃Si₃), tetramethylsilane (Si(CH₃)₄), tetrakis(dimethylamide) hafnium (TDMAHf (Hf[N(CH₃)(C₂H₅)]), bis(2,2,6,6-tetramethyl-3,5-heptanedionato) magnesium (Mg(TMHD)₂, (Mg(C₁₁H₁₉O₂)₂)), bis(methylcyclopentadienyl)magnesium (C₁₄H₁₈Mg₁₀), and the like.

The conditions of the film forming step by PVD can be appropriately determined according to the material of the layer or the substrate. For example, since the glass transition temperature (Tg) of the substrate is about 140 to 150° C. in the case of preparing the mixed layer when a plastic resin lens is adopted as the substrate, the film formation temperature is preferably 100° C. or lower from the viewpoint of suppressing the shape change of the substrate. As described above, the above conditions can be appropriately determined.

### [Manufacturing Apparatus]

The above manufacturing method can be performed by an apparatus including a film forming apparatus by PVD and a CVD gas supply apparatus capable of supplying a CVD gas into a chamber of the film forming apparatus. Such a manufacturing apparatus can be configured, for example, by externally connecting a CVD gas supply apparatus to a vacuum vapor deposition apparatus manufactured by SHINCRON Corporation equipped with a plasma gun, and such a configuration makes it possible to perform vacuum vapor deposition (PVD) while causing a CVD gas to flow into a chamber in the vacuum vapor deposition apparatus.

In a film forming apparatus by PVD, vacuum vapor deposition can be performed, for example, by irradiating a dielectric material placed in a crucible with an electron beam to evaporate the material. In addition, by flowing a reactive gas (such as O₂ or N₂) into the chamber, it is possible to prepare a dielectric film of any oxide, nitride, oxynitride, or the like derived from the dielectric material.

On the other hand, the CVD gas supply apparatus can cause an arbitrary gas to flow at an arbitrary flow rate by appropriately replacing the raw material tank and the flow meter included in the CVD gas supply apparatus according to the gas type. The CVD gas introduced into the chamber reacts with the dielectric material evaporated by electron beam irradiation to prepare a dielectric film doped with an organic substance (that is, the above-described mixed layer).

In addition, by performing plasma irradiation (ion irradiation, heat, or the like) during film formation, it is possible to promote the film formation reaction. In addition, applying an RF bias to the substrate side is also effective for promoting the reaction. Hereinafter, a manufacturing method applied to the manufacturing method of the present embodiment will be described in more detail.

### <First Example of Manufacturing Apparatus>

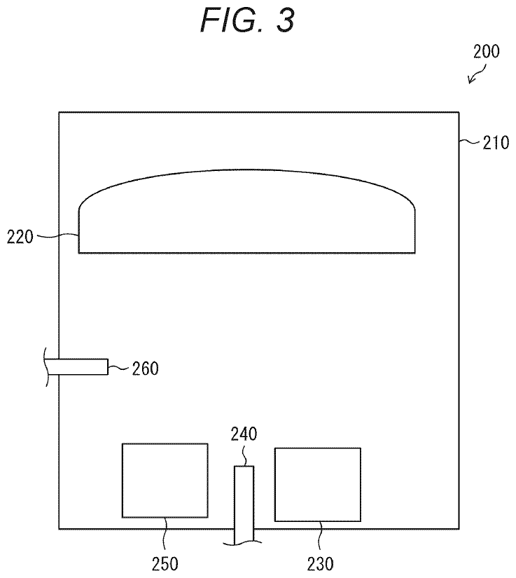

As illustrated in FIG. 3, a manufacturing apparatus 200 includes a vapor deposition dome 220 at an upper portion in a chamber 210. A deposition source 230 and a plasma gun 250 are disposed at a position facing the vapor deposition dome 220 in the chamber 210. In the chamber 210, a first gas introduction port 240 for supplying a reactive gas and a second gas introduction port 260 for supplying a precursor gas are disposed toward a space between the vapor deposition dome 220, and the deposition source 230 and the plasma gun 250.

The chamber 210 is configured to be decompressible. The vapor deposition dome 220 is configured such that a plurality of substrates described later can be installed. The vapor deposition source 230 includes, for example, a crucible and an electron gun that irradiates the crucible with an electron beam. The plasma gun 250 is a plasma source in which the intensity of plasma is variable by changing a parameter such as a discharge voltage. The first gas introduction port 240 is connected to a supply source (for example, a cylinder) of a reactive gas such as oxygen, and is configured to be able to supply these gases into the chamber 210 at a desired flow rate. The second gas introduction port 260 is connected to a supply source (for example, a cylinder) of a precursor gas, and is configured to be able to supply the gas into the chamber 210 at a desired flow rate.

As described above, the manufacturing apparatus 200 includes a PVD film forming mechanism by vacuum vapor deposition, and further includes a precursor gas supply mechanism. Such a manufacturing apparatus 200 can be configured by, for example, adding a precursor gas supply apparatus to an existing PVD film forming apparatus.

In the production of the optical thin film, a substrate such as a resin lens is placed on the vapor deposition dome 220. Then, the crucible of the vapor deposition source 230 is filled with magnesium fluoride or another dielectric material such as titanium oxide as necessary. A supply source of a reactive gas and an inert gas for discharge is connected to the first gas introduction port 240, and a cylinder of a precursor gas is connected to the second gas introduction port 260.

A precursor gas is supplied from the second gas introduction port 260, and a reactive gas and an inert gas for discharge, for example, argon gas are supplied from the first gas introduction port 240 into the chamber 210, and the inside of the chamber 210 is further depressurized to a specific degree of vacuum. The argon gas may be supplied by another supply apparatus (not illustrated). In this way, an atmosphere of the precursor gas and the reactive gas is formed in the chamber 210. Next, the crucible of the vapor deposition source 230 is irradiated with an electron beam from an electron gun. Further, for example, argon plasma is emitted from the plasma gun 250 into the chamber 210.

The dielectric material in the crucible is deposited on the surface of the substrate in the vapor deposition dome 220 by plasma-assisted vacuum vapor deposition to form a layer. On the other hand, the precursor gas supplied from the second gas introduction port 260 into the chamber 210 is deposited on the surface of the substrate in the vapor deposition dome 220 while reacting with the reactive gas from the first gas introduction port 240 in the presence of the argon plasma from the plasma gun 250. In this way, a mixed layer (the above-mentioned MO mixed layer or DO mixed layer) in which the reactant of the organometallic compound is mixed in the PVD layer of the dielectric material is prepared on the substrate.

When the operation of the vapor deposition source 230 is stopped, only the reactant of the organometallic compound is deposited on the substrate, and the adhesion layer described above is prepared. When the supply of the precursor gas from the second gas introduction port 260 is stopped, only the film derived from the PVD dielectric material is deposited on the substrate, and the above-described high refractive index layer or low refractive index layer is prepared. By appropriately controlling the operation of the manufacturing apparatus 200 in this manner, the adhesion layer and the multilayer film described above can be formed on the surface of the substrate.

As described above, in the present embodiment, it is possible to prepare a mixed layer by simultaneously performing two kinds of film forming methods of PVD and CVD. The mixed layer has physical properties different from physical properties of a PVD layer using a mixture of a dielectric material and an organometallic material compound as a raw material. This is considered because the growth mechanism is different between the mixed layer which is prepared in synchronization of PVD and CVD as in the present embodiment and the layer formed by the PVD film formation of the mixture.

A typical characteristic of the mixed layer in the present embodiment is to have compressive stress. In the present embodiment, a high refractive index substance that tends to have a tensile stress is deposited on the substrate by PVD, and an organometallic compound (an organosilicon compound in the example) having a strong compressive stress is deposited on the substrate by CVD, so that the tensile stress of the PVD layer that originally becomes a layer having a tensile stress is reduced or changed to a compressive stress. Therefore, as described above, even in a multilayer film including the above-described mixed layer and the high refractive index layer having tensile stress, the optical thin film of the present embodiment can have compressive stress as a whole.

In addition, the stress of the optical thin film can be controlled by adjusting quantitative conditions of the organometallic material compound in the layer to be formed, such as the flow rate of the precursor gas. Therefore, it is possible to prepare an optical thin film having a high refractive index and a large compressive stress depending on the conditions.

As a result, it is possible to obtain an optical thin film of a multilayer film which has the same reflectance as that of a conventional multilayer film of a high refractive index layer and a low refractive index layer and does not cause cracks even at a high temperature of 110° C. or higher. Further, according to the embodiment of the present invention, the MO mixed layer exhibits excellent optical characteristics of MgF₂ in which the tensile stress is strong and cracks are easily generated but excellent optical characteristics are exhibited, and further, the MO mixed layer reduces the strong tensile stress of MgF₂. Therefore, even when the optical thin film of the present embodiment is adopted as an optical thin film for a plastic lens, an optical thin film having high durability (not causing cracks) can be obtained.

### <Second Example of Manufacturing Apparatus>

Another example of the device that can be used in the manufacturing method of the present embodiment will be described below. Note that, in description of the following example of the manufacturing apparatus, for convenience of description, members identical in function to the members described in the above-described examples are denoted with the same reference signs and thus duplicate descriptions thereof will be omitted.

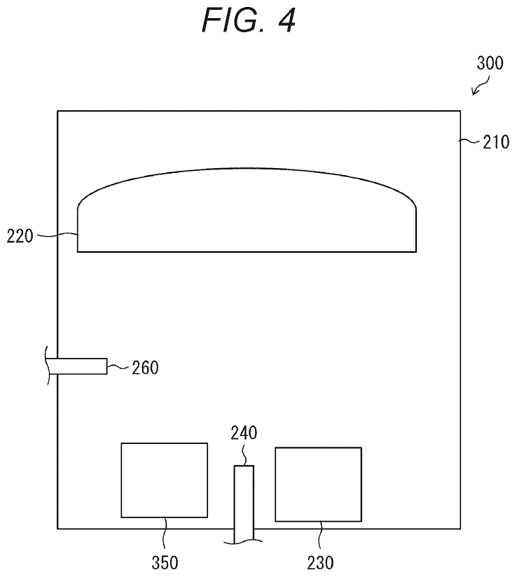

FIG. 4 schematically illustrates a configuration of a second example in the manufacturing apparatus of an optical thin film of the present embodiment. As illustrated in FIG. 4, a manufacturing apparatus 300 has the same configuration as the manufacturing apparatus 200 described above except for including an ion gun 350 instead of the plasma gun 250.

The ion gun 350 emits cations derived from argon gas toward the substrate of the vapor deposition dome 220, for example. The dielectric material in the crucible is deposited on the surface of the substrate in the vapor deposition dome 220 by ion-assisted vacuum vapor deposition to form a layer. The precursor gas supplied from the second gas introduction port 260 into the chamber 210 is deposited on the surface of the substrate in the vapor deposition dome 220 while reacting with the reactive gas from the first gas introduction port 240 in the presence of the ions from the ion gun 350.

The manufacturing apparatus 300 can prepare the mixed layer of the present embodiment similarly to the manufacturing apparatus 200 described above. The manufacturing apparatus 300 is advantageous from the viewpoint of enhancing the denseness of the layer to be prepared.

### <Third Example of Manufacturing Apparatus>

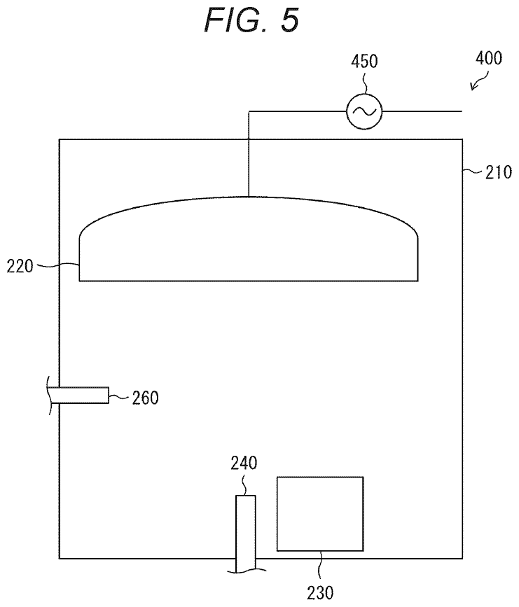

FIG. 5 schematically illustrates a configuration of a third example in the manufacturing apparatus of an optical thin film according to the present embodiment. As illustrated in FIG. 5, a manufacturing apparatus 400 has the same configuration as the manufacturing apparatus 200 described above except that a high-frequency power supply 450 is provided instead of the plasma gun 250.

The high-frequency power supply 450 applies a negative charge to the substrate. The dielectric material in the crucible is, for example, ionized and positively charged, attracted to the substrate, and deposited. The precursor gas supplied from the second gas introduction port 260 into the chamber 210 is deposited on the surface of the substrate in the vapor deposition dome 220 while reacting with the reactive gas from the first gas introduction port 240 in the presence of plasma by voltage application to the substrate of the high-frequency power supply 450.

The manufacturing apparatus 400 can prepare the mixed layer of the present embodiment similarly to the manufacturing apparatus 200 described above. The manufacturing apparatus 400 is advantageous from the viewpoint of enhancing the adhesion of the layer to be prepared to the substrate.

### <Fourth Example of Manufacturing Apparatus>

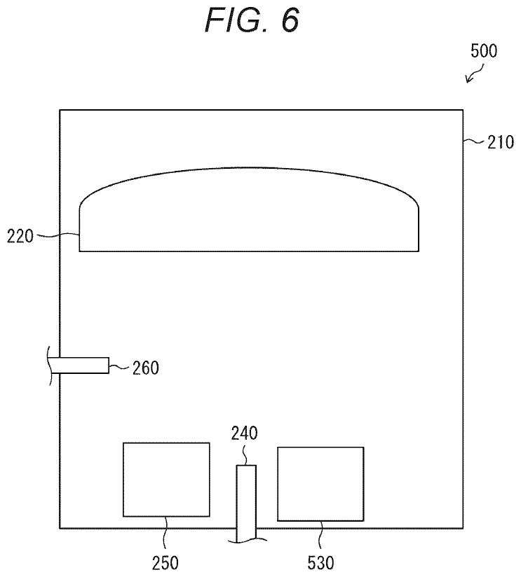

FIG. 6 schematically illustrates a configuration of a fourth example in the manufacturing apparatus of an optical thin film according to the present embodiment. As illustrated in FIG. 6, a manufacturing apparatus 500 has the same configuration as the manufacturing apparatus 200 described above except that a sputtering source 530 is provided instead of the vapor deposition source 230.

The sputtering source 530 includes a power supply that charges a target of a metal material of a dielectric material. Positive argon plasma generated by, for example, the plasma gun 250 is caused to collide with the negatively charged target, and metal atoms repelled from the surface of the target react with the reactive gas and are deposited on the substrate to form a layer of dielectric material. On the other hand, as described above, the precursor gas is deposited on the surface of the substrate while reacting with the reactive gas in the presence of plasma.

The manufacturing apparatus 500 can prepare the mixed layer of the present embodiment similarly to the manufacturing apparatus 200 described above. The manufacturing apparatus 500 is advantageous from the viewpoint of enhancing the adhesion of the layer to be prepared to the substrate.

### <Fifth Example of Manufacturing Apparatus>

FIG. 7 schematically illustrates a configuration of a fifth example in the manufacturing apparatus of an optical thin film according to the present embodiment. A manufacturing apparatus 600 includes a chamber 610, a stage 620, a sputtering source 530, a first gas introduction port 240, a plasma radical source 650, and a second gas introduction port 260.

The chamber 610 has a first chamber in which the sputtering source 530 is disposed and a second chamber in which the plasma radical source 650 is disposed. The first chamber and the second chamber communicate with each other. The stage 620 is a member that holds the substrate on the surface. The stage 620 is disposed across the first chamber and the second chamber, and is disposed in the chamber 610 so as to be rotatable in a direction in which the held substrate alternately passes through the first chamber and the second chamber. The plasma radical source 650 generates, for example, an argon plasma and also generates radicals of a reactive gas.

When the substrate on the stage 620 is in the first chamber, a layer of a metal material of a dielectric material is formed on the surface of the substrate by sputtering. When the substrate on the stage 620 is in the second chamber, radicals of the reactive gas react with the metal material in the layer on the substrate. In this way, a layer of dielectric material is prepared on the substrate by reactive sputtering. On the other hand, as described above, the precursor gas is deposited on the surface of the substrate while reacting with the reactive gas in the presence of plasma.

The manufacturing apparatus 600 can prepare the mixed layer of the present embodiment similarly to the manufacturing apparatus 200 described above. The manufacturing apparatus 600 is advantageous from the viewpoint of forming a thinner layer.

### <Other Examples of Manufacturing Apparatus>

Each of the above-described manufacturing apparatuses may further include a mechanism for quantifying plasma or ions generated in the chamber, or may further include a mechanism for analyzing the composition of gas in the chamber, such as a Q-mass (quadrupole mass spectrometer). As described above, the manufacturing apparatus according to the present embodiment may further include a mechanism that detects a condition in the chamber.

In addition, the operation of film formation in the manufacturing apparatus described above may be performed by an operator or may be performed by a control device such as a computer. The control device may be, for example, a device that acquires information of film forming conditions according to information of a layer material, a layer stress, and a layer thickness according to input signals of these signals, and outputs a control signal according to the information to the manufacturing apparatus. The information on the film forming conditions may be data obtained when the film forming conditions have been previously performed, data calculated on the basis of a correlation obtained in advance between the conditions, or data obtained by machine learning, regression analysis, or the like. The control device may be replaced with a logic circuit that implements some or all of the functions of the control block in the control device, an integrated circuit in which the logic circuit is formed, or a quantum computer that implements the functions of the control block. Furthermore, in a case where the manufacturing apparatus further includes a mechanism that detects a condition in the chamber, the control device may include a functional configuration that further refers to a signal of the detected condition and outputs a control signal.

In addition, the high-frequency power supply 450 of the manufacturing apparatus 400 may be another power supply as long as PVD and CVD are compatible. For example, the manufacturing apparatus may include a direct current power supply instead of the high frequency power supply, or may include both the high frequency power supply and the direct current power supply and apply a superimposed voltage by both the power supplies.

### [Optical Element]

An optical element according to an embodiment of the present invention includes a substrate and the optical thin film of the present embodiment formed on a surface of the substrate. The substrate is a member that can be an optical element exhibiting specific optical characteristics by itself. Examples of substrates include lenses, prisms, filters and beam splitters. In the optical element of the present embodiment, the optical thin film may be disposed on one or both of the light incident portion and the light emitting portion of the substrate, or may be formed on the entire surface of the substrate.

The material of the substrate is usually a material having optical transparency, and examples thereof include glass and resin. As described above, the optical thin film of the present embodiment has high antireflection characteristics (low reflectance) and compressive stress. On the other hand, since plastic resin has a linear expansion coefficient about 10 times larger than that of glass, plastic resin is more easily deformed (expanded or contracted) by heat. Since the optical thin film of the present embodiment has compressive stress, the optical thin film has high followability to deformation in the planar direction. Therefore, from the viewpoint that the effect of preventing cracks due to thermal deformation is more remarkable, in the present embodiment, the substrate is preferably made of a plastic resin, and in such a form, it is more advantageous since the reliability of the optical element in a temperature environment is further enhanced.

Examples of the plastic resin as a material of the substrate include a plastic resin suitable as a material of an optical lens, and more specific examples thereof include a cycloolefin resin, a polycarbonate resin, an acrylic resin, an epoxy resin, a fluororesin, a silicone resin, a polyethylene resin, a polypropylene resin, a polyvinyl chloride resin, a polyvinylidene chloride resin, a polystyrene resin, a polyvinyl acetate resin, a polyamide resin, a polyacetal resin, a fluorene polyester resin, a modified polyphenylene ether resin, a polybutylene terephthalate resin, a polyethylene terephthalate resin, and a liquid crystal polymer. Further, as a material of the in-vehicle plastic lens, a highly heat-resistant resin developed as an in-vehicle grade is more preferable. The substrate may be a resin substrate obtained by further applying a hard coat containing the resin on a resin lens.

In addition, in the present embodiment, the optical thin film may include other layers other than the above-described mixed layer as long as the effect of the present invention can be obtained.

For example, the optical element may further include an adhesion layer interposed between the substrate and the optical thin film. The adhesion layer is a layer that enhances adhesion between the substrate and the optical thin film (substrate and MO mixed layer, or substrate and layer closest to substrate side of multilayer film). The adhesion layer may be a layer composed of the above-described organometallic material compound. The layer composed of the organometallic material compound can be prepared, for example, by CVD of the above-mentioned organometallic compound. It is preferable that the optical thin film has an adhesion layer, for example, from the viewpoint of enhancing the adhesion of the optical thin film on the surface of the material of the resin substrate.

Furthermore, for example, the optical element may further include a protective film on the surface of the optical thin film. The protective film is formed on the surface of the optical thin film and is a layer for preventing damage to the optical thin film (for example, a layer for preventing damage to the surface). The protective film may be a layer formed by PVD of the dielectric material described above. It is preferable that the protective film has a film thickness sufficient to prevent damage to the optical thin film, and has a film thickness insufficient to exhibit an optical function, from the viewpoint of suppressing the influence on the optical characteristics of the optical thin film while exhibiting a desired function, and it is possible to further improve the reliability of the optical element by suppressing the damage of the surface of the optical thin film. From such a viewpoint, the protective film is preferably sufficiently thin, and the thickness of the protective film is preferably 50 nm or less. The thickness of the protective film may be, for example, 5 nm or more from the viewpoint of preventing damage to the optical thin film.

Further, for example, the optical element may further have an antifouling film on the surface of the optical thin film. The antifouling film is a layer for preventing adhesion of dirt (for example, adhesion of fine powder or oil) to the surface of the optical thin film. The antifouling film may be, for example, a fluorine-based water-repellent and oil-repellent film. The fluorine-based water-repellent and oil-repellent film can be prepared by, for example, wet coating or vacuum vapor deposition. The thickness of the antifouling film may be, for example, 10 to 50 nm from the viewpoint of suppressing the influence on the optical characteristics of the optical thin film and from the viewpoint of sufficiently exhibiting the desired antifouling effect.

Further, for example, the optical element may further have a conductive film on the surface of the optical thin film. The conductive film is a layer for shielding or preventing charging of electromagnetic wave noise. The conductive film may be, for example, ITO or IZO. The conductive film can be prepared by, for example, sputtering or vacuum vapor deposition. The thickness of the conductive film may be, for example, 5 to 50 nm from the viewpoint of suppressing the influence on the optical characteristics of the optical thin film and from the viewpoint of sufficiently exhibiting the desired conductive effect.

The other layers mentioned above preferably do not have such optical characteristics as to substantially affect the designed optical characteristics of the optical thin film. On the other hand, since the other layers are formed so as to overlap the optical thin film, the other layers can affect the film stress of the optical thin film. Therefore, when the optical element further includes the other layers, the film stress of the optical thin film in the optical element may include the film stress by the other layers. The material of the other layers can be appropriately selected from the viewpoint of such film stress. For example, the adhesion layer is preferably a layer composed of the organometallic material compound described above also from the viewpoint that the entire optical thin film has a sufficiently small tensile stress or a sufficiently high compressive stress with respect to a multilayer film (or a specific DO mixed layer described above) that can contain a material having a tensile stress.

As described above, the optical thin film of the present embodiment has high followability to deformation in the planar direction. The optical thin film of the present embodiment is useful for coating a plastic lens having a high heat resistance specification that has been demanded recently. In addition, the optical element of the present embodiment is useful for a lens mainly assumed to be used in a high-temperature environment such as a vehicle.

### [Optical Apparatus]

The optical apparatus according to the embodiment of the present invention includes the above-described optical element. Examples of the optical apparatus include a zoom lens, a single lens reflex camera, an in-vehicle camera, a surveillance camera, glasses, binoculars, and a telescope. Since the optical apparatus of the present embodiment has the above-described optical element, a desired optical function is exhibited even in an environment where a temperature change is large, and high reliability in the environment can be obtained.

### SUMMARY

As a countermeasure against cracks of the antireflection film for a plastic lens under a high temperature condition, control of film stress can be an effective means. Cracks of the film are likely to occur when the tensile stress is large. Therefore, as a countermeasure against cracks of the antireflection film, it is effective to control the entire film stress to be zero or close to the compressive stress so that the entire stress does not become the tensile stress.

However, the film stress of the antireflection film is difficult to control because the range of the film stress is determined by the film forming material. For example, MgF₂ has a low refractive index as compared with other low refractive index substances such as SiO₂, and thus is widely used as a low refractive index substance of the outermost layer. However, since MgF₂ has a strong tensile stress, and it is difficult to find conditions under which cracks do not occur, there is almost no example in which MgF₂ is employed in a plastic lens for a vehicle or the like requiring high heat resistance. Since it is generally known that the lower the refractive index of the outermost layer, the lower the reflection of the antireflection film, the antireflection film not using MgF₂ is inferior in performance to an antireflection film using MgF₂ on a glass substrate.

Furthermore, in the conventional method, as described above, the film stress is adjusted by adjusting various conditions such as a stacking combination of film materials, film forming conditions, and film thickness, but there is a limit in a controllable range in view of mechanical characteristics or optical characteristics other than stress. Even when the film stress is adjusted for improving the heat resistance, there is a problem that the entire film thickness becomes thick and the antireflection performance becomes insufficient.

As described above, in the conventional technique, in the case of an antireflection film that requires not only optical performance but also environmental resistance, a material that is easily subjected to stress adjustment is selected from existing film forming materials, and the film thickness is limited, thereby ensuring heat resistance. Therefore, it is difficult to use a material whose film has a strong tensile stress even if the material is useful in terms of optical characteristics, such as MgF₂, and naturally, the reflectance tends to be higher than that of an antireflection film using MgF₂.

Specifically, focusing on the countermeasures in the aforementioned patent documents, for example, the aforementioned JP 2021-21893 A has mainly focused on improvement of high-temperature durability, but there is no description of specific numerical values, and there is no description of MgF₂ in the examples. Therefore, it is assumed that it is difficult to introduce MgF₂ with the technique described in JP 2021-21893 A.

In addition, the technique described in JP 2019-144552 A is equivalent to stress control, and it is described in the present text that MgF₂ may be used. However, there is no example in which MgF₂ is used in the examples. Therefore, it is assumed that it is difficult to use MgF₂ even with the technique described in JP 2019-144552 A. In addition, the film thickness ratio (30 to 70%) of the innermost layer described in the claims in JP 2019-144552 A is considered to have a low degree of freedom in thin film design. Actually, the film thickness ratios of the innermost layers of the three examples are only 45 to 50%.

In addition, the technique described in JP 2015-129129 A is considered to have the same meaning as the stress control as in the technique of JP 2019-144552 A. However, J P 2015-129129 A does not describe the use of MgF₂. In the example of JP 2015-129129 A, when the heat resistance is 120° C. or higher, the total film thickness is 600 nm or more, and the reflectance is high, so that high heat resistance and antireflection performance are in a trade-off relationship.

Further, in JP 2019-66600 A, the low refractive index substance to be used is a SiO₂ system, and MgF₂ is not described.

The antireflection film is often formed by stacking two or more kinds of film substances having different refractive indexes, and the kind of each substance is generally a simple substance or a mixture or a compound of two or more kinds of metal oxides. Although the film stress can be adjusted by a combination of film substances or a film thickness, MgF₂ has particularly strong tensile stress, and even if such adjustment is performed, the film of MgF₂ cracks at a high temperature. It cannot be used for plastic lenses under high temperature.

On the other hand, in the embodiment of the present invention, a composite film deposition in which CVD deposition of an organosilicon compound is performed simultaneously with conventional MgF₂ deposition is performed. By replacing the MgF₂ layer having the tensile stress in this manner with the MO mixed layer having the organic component, the stress inherent to the film itself can be changed, so that an arbitrary internal stress in a wider range can be set. As a result, the compressive stress of the entire film is increased, and the occurrence of cracks can be suppressed even in a high-temperature environment. In addition, since MgF₂ can also be used, the reflectance is also advantageous compared to the related art.

As is apparent from the above description, the first aspect of the present invention is an optical thin film including one or more MO mixed layers (11) in which an organometallic compound is mixed in a layer formed by physical vapor deposition of magnesium fluoride. According to the first aspect, it is possible to realize a new optical thin film that realizes exhibition of desired optical characteristics and suppression of occurrence of cracks.

According to a second aspect of the present invention, in the first aspect, the optical thin film is a multilayer film formed by stacking two or more dielectric layers having different refractive indexes, and includes an MO mixed layer as at least one of the dielectric layers. The second aspect is more effective from the viewpoint of enhancing optical characteristics such as antireflection characteristics in the optical thin film.

According to a third aspect of the present invention, in the first aspect or the second aspect, the dielectric layer is a layer of an oxide, an oxynitride, or a nitride of a dielectric material containing one or more elements selected from a group consisting of Ti, Zr, Ta, La, Nb, Hf, Al, Si, Pr, Y, and Ce, the dielectric material being formed by physical vapor deposition. The third aspect is more effective from the viewpoint of achieving desired optical characteristics of the optical thin film.

According to a fourth aspect of the present invention, in any one of the first to third aspects, the dielectric layer includes a DO mixed layer in which an organometallic compound is mixed in a layer of an oxide, an oxynitride, or a nitride of a dielectric material containing one or more elements selected from a group consisting of Ti, Zr, Ta, La, Nb, Hf, Al, Si, Pr, Y, and Ce, the dielectric material being formed by physical vapor deposition. The fourth aspect is more effective from the viewpoint of further improving optical characteristics such as antireflection characteristics in the optical thin film and further optimizing film stress of the optical thin film.

According to a fifth aspect of the present invention, in any one of the first to fourth aspects, the organometallic compound is an organic compound containing one or more elements selected from a group consisting of Si, Al, Ti, Hf, and Mg. The fifth aspect is more effective from the viewpoint of achieving desired antireflection characteristics in an optical thin film that is a multilayer film.

According to a sixth aspect of the present invention, in any one of the first to fifth aspects, an MO mixed layer is included as an optical outermost layer. The sixth aspect is more effective from the viewpoint of suppressing damage to the optical functional layer.

According to a seventh aspect of the present invention, in any one of the first to sixth aspects, when the tensile stress is positive and the compressive stress is negative, the optical thin film has a film stress of +200 to −1000 MPa. The seventh aspect is more effective from the viewpoint of preventing occurrence of cracks at a high temperature.

According to an eighth aspect of the present invention, in any one of the first to seventh aspects, the optical thin film has a reflectance of light having a wavelength of 450 to 600 nm of 0.5% or less, or a reflectance of light having a wavelength of 400 to 850 nm of 1.5% or less. The eighth aspect is more effective from the viewpoint of achieving desired optical characteristics according to a specific application of the optical thin film.

A ninth aspect of the present invention is an optical element including a substrate and the optical thin film according to any one of the first to eighth aspects supported on the substrate. According to the ninth aspect, it is possible to realize an optical element having high reliability by a new optical thin film that realizes exhibition of desired optical characteristics and suppression of occurrence of cracks.

According to a tenth aspect of the present invention, in the ninth aspect, the optical element further includes an adhesion layer (14) interposed between the substrate and the optical thin film. The tenth aspect is more effective from the viewpoint of enhancing adhesion between the substrate and the optical thin film.

According to an eleventh aspect of the present invention, in the ninth aspect or the tenth aspect, the optical thin film further includes a protective film having a film thickness of 50 nm or less on a surface thereof. The eleventh aspect is more effective from the viewpoint of suppressing damage to the surface of the optical thin film and enhancing the reliability of the optical element.

According to a twelfth aspect of the present invention, in any one of the ninth to eleventh aspects, the substrate is made of a plastic resin. The twelfth aspect is more effective from the viewpoint of further increasing the reliability of the optical element in the temperature environment.

According to a thirteenth aspect of the present invention, an optical apparatus is provided which includes the optical element according to any one of the ninth to twelfth aspects. According to the thirteenth aspect, it is possible to realize an optical apparatus having high reliability by a new optical thin film that realizes exhibition of desired optical characteristics and suppression of occurrence of cracks.

According to a fourteenth aspect of the present invention, there is provided a manufacturing method of an optical thin film, comprising forming a layer of a dielectric material on a substrate by physical vapor deposition in an atmosphere containing an organometallic compound and a reactive gas to form a mixed layer in which the organometallic compound is mixed in the layer of an oxide, an oxynitride, or a nitride of the dielectric material, in which the forming of the mixed layer includes forming an MO mixed layer in which the organometallic compound is mixed in a layer by physical vapor deposition of magnesium fluoride using magnesium fluoride as the dielectric material. According to the fourteenth aspect, it is possible to provide a new optical thin film that realizes exhibition of desired optical characteristics and suppression of occurrence of cracks.

An aspect of the present invention can provide an optical thin film having both optical characteristics by magnesium fluoride and film stress capable of heat-resistant use, and having a high degree of freedom in film design. The present invention having such effects is expected to contribute to the achievement of the goal 9 of the United Nations' sustainable development goal (SDGs), for example, “to build the foundation of industry and technological innovation”.

The present invention is not limited to the above-described embodiments, and thus various modifications can be made within the scope of the claims. Embodiments obtained by combining as appropriate the respective technical means disclosed in different embodiments are to be included in the technical scope of the present invention.

### EXAMPLES

An example of the present invention will be described below. The present example is an antireflection film for a lens mainly assumed to be used in a high-temperature environment such as a vehicle. In the present example, unless otherwise specified, an optical thin film is formed on a lens of a cycloolefin copolymer.

### First Example

Simultaneous deposition of magnesium fluoride and an organosilicon compound has been performed. A manufacturing apparatus including a PVD film forming mechanism by vacuum vapor deposition and a precursor gas supply mechanism as illustrated in FIG. 2 is prepared, a crucible of the PVD film forming mechanism is filled with granular magnesium fluoride, and a gas of a siloxane compound is prepared so as to be able to be supplied to the precursor gas supply mechanism. In addition, argon gas for discharge and oxygen gas as reactive gas are prepared so as to be able to be supplied to the chamber of the vacuum vapor deposition apparatus. PVD film formation of magnesium fluoride has been performed at a flow rate of siloxane gas of 10 sccm to perform mixed film formation, thereby obtaining an optical thin film 1 including a monolayer MO mixed layer in which an organometallic compound is mixed in a layer by physical vapor deposition of magnesium fluoride.

### Second to Fourth Examples

An optical thin film 2 has been obtained in the same manner as in the first example except that the flow rate of the siloxane gas is 30 sccm. In addition, an optical thin film 3 has been obtained in the same manner as in the first example except that the flow rate of the siloxane gas is 50 sccm. Furthermore, an optical thin film 4 has been obtained in the same manner as in the first example except that the flow rate of the siloxane gas is 80 sccm.

### First Comparative Example

A monolayer optical thin film C1 made of MgF₂ has been obtained in the same manner as in the first example except that the flow rate of the siloxane gas is set to 0 sccm.

The film forming conditions of the optical thin films 1, 2, and C1 are shown in Table 1.

TABLE 1

| | | Flow rate | | | | |
|---|---|---|---|---|---|---|
| | Flow rate of | of MFC gas | | | Discharge condition | |
| Optical thin | siloxane gas | O₂ | Ar | Deposition | Discharge | Discharge |
| film No. | [sccm] | [sccm] | [sccm] | rate [Å/sec] | voltage [V] | current [A] |
| 1 | 10 | 8 | 16 | 10 | 100 | 20 |
| 2 | 30 | 8 | 16 | 10 | 100 | 20 |
| 3 | 50 | 8 | 16 | 10 | 100 | 20 |
| 4 | 80 | 8 | 16 | 10 | 100 | 20 |
| C1 | 0 | 8 | 16 | 10 | 100 | 20 |

### [Evaluation (Monolayer Film)]

### [Optical Constant and Film Thickness]

Spectral reflectance and transmittance of each of the optical thin films 1 to 4 and C1 at a wavelength of 550 nm have been measured using a spectrophotometer U-4100 manufactured by Hitachi High-Technologies Corporation, and an optical constant (refractive index at a wavelength of 550 nm) of the optical thin film has been calculated from the results.

### [Film Stress]

The film stress of the optical thin films 1 to 4 and C1 has been determined using a substrate curvature method. At the time of film formation, a cover glass having a thickness of 0.15 mm has been placed on the vapor deposition dome, and the amount of warpage (height from the reference surface) of the cover glass before and after film formation has been measured using a laser displacement meter. Then, the amount of displacement of the amount of warpage before and after film formation has been determined, and the film stress (tensile stress) has been calculated using the following Stoney's expression. The meaning of each character in the following expression is as follows. In the film stress, a positive value represents the magnitude of the tensile stress, and a negative value represents the magnitude of the compressive stress.
Es: Young's modulus of cover glass
ν: Poisson's ratio of cover glass
b: Thickness of cover glass
L: Length of cover glass
d: Thickness of optical thin film (layer)
δ: Warpage displacement amount

$$σ = \frac{{E}_{s} {b}^{2} δ}{3 ( 1 - v ) {L}^{2} d} \qquad [ Math . 1 ]$$

### [Composition]

For each of the optical thin films 1, 2, and C1, a sample has been irradiated with an electron beam having an accelerating voltage of 10 kV and subjected to spectrum analysis using a scanning electron microscope JSM-6500F manufactured by JEOL Ltd. and an energy dispersive X-ray analyzer Genesis manufactured by EDAX Corporation, and the various element ratios in the optical thin film have been determined by a ZAF method. The Si element ratio is a ratio of the amount of Si element to the total amount of Si element and Mg element in the film. In this evaluation, an Al plate substrate has been used as a substrate that does not interfere with both Mg and Si in the measurement of the composition, and each optical thin film has been formed on the substrate so that the substrate does not affect the quantification of elements. In addition, at the time of analysis, Pt coating has been applied by a sputtering apparatus as an antistatic pretreatment of the sample. For the optical thin films 3 and 4, the ratio of Si element in each optical thin film has been calculated based on the correlation (represented by the calibration curve) obtained from the measured values of the optical thin films 1, 2 and C1.

### [Indentation Hardness, Young's Modulus]

The film hardness (indentation hardness) and Young's modulus of each of the optical thin films 1, 2 and C1 have been measured using a nanoindenter manufactured by ELIONIX Corporation. The measurement load has been 0.1 mN. Measurement has been performed at specific nine measurement points in each optical thin film, an average value of the measured values has been determined, and the average value has been defined as the indentation hardness and Young's modulus of each optical thin film. For the optical thin films 3 and 4, the indentation hardness and Young's modulus of each optical thin film have been calculated based on the correlation (represented by the calibration curve) obtained from the measured values of the optical thin films 1, 2 and C1.

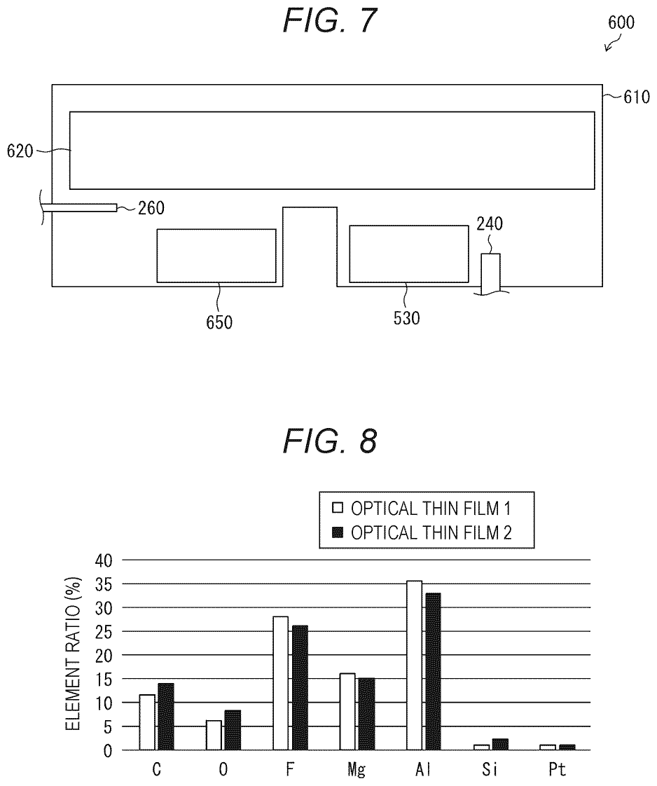

The evaluation results of the optical thin films 1 to 4 and C1 are shown in Table 2. Detection results of various elements in the optical thin films 1 and 2 are illustrated in FIG. 8.

TABLE 2

| | Optical | | | | |
|---|---|---|---|---|---|
| | constant, | Stress | | | |
| Optical | refractive | after | Si element | Indentation | Young's |
| thin | index | 24 h | ratio | hardness | modulus |
| film No. | @550 nm | [MPa] | [%] | [GPa] | [GPa] |
| 1 | 1.392 | 201 | 6.1 | 2.21 | 99 |
| 2 | 1.409 | 50 | 14.1 | 2.01 | 75 |
| 3 | 1.422 | −188 | 23.7 | 1.80 | 45 |
| 4 | 1.443 | −520 | 37.5 | 1.49 | 22 |
| C1 | 1.389 | 400 | 0 | 2.32 | 156 |

### [Abrasion Test]

For each of the optical thin films 1 and C1, methanol has been impregnated into a wiper (Ozu-Sangyo Co., Ltd., Dusper (registered trademark) K4), the optical thin film on the surface of the resin lens has been wiped back and forth 10 times with a load of about 200 g, and then the wiped surface has been visually observed. In the visual confirmation, the optical thin film has been observed by changing the angle of illumination light applied to the optical thin film.

As a result, in the optical thin film 1, a white streaky pattern has been observed depending on how the illumination light is applied, but since the pattern has been not observed at all in some cases, it has been confirmed that the pattern is not a scratch but uneven wiping. As described above, no scratch has been observed on the surface of the optical thin film 1.

On the other hand, in the optical thin film C1, since a white streak-like pattern is observed regardless of how the illumination light is applied, it has been confirmed that the pattern is a scratch. As described above, in the optical thin film C1, scratches have been observed in this test.

### [Measurement of Friction Coefficient]

Each of the optical thin films 1 and C1 has been measured under the conditions of a load of 200 g, a moving speed of 100 mm/sec, and a moving distance of 30 mm using a surface property measuring machine TYPE: 14FW manufactured by Shinto Scientific Co., Ltd. A φ10 cylindrical SUS indenter has been used as a contact in contact with the test piece. The contact portion of the contact with the test piece is a flat portion of the cylinder. Then, the static friction coefficient has been determined from the measured values. As a result, the static friction coefficient of the optical thin film 1 has been 0.74, and the static friction coefficient of the optical thin film C1 has been 1.38.

### [Consideration (Monolayer Film)]

As shown in Tables 1 and 2, the tensile stress of the film stress has decreased as the flow rate of the organosilicon compound has increased. In addition, as the amount of the organosilicon compound in the optical thin film increases, the indentation hardness and the Young's modulus decrease. This is assumed to be an influence of containing an organic skeleton in the film.

According to the above results, it is considered that by using the MO mixed layer in the present invention for the multilayer film, it is possible to suppress the tensile stress of the film stress of the entire multilayer film and to control the tensile stress to the compression side, thereby making it possible to prepare an antireflection film that is low in reflection and is less likely to be cracked at a high temperature.

In addition, according to the measurement result of the friction coefficient, it can be said that the MO mixed layer in the present invention has a lower static friction coefficient than a conventional MgF₂ film, and has a surface property that is less likely to be worn than a normal MgF₂ film. This is considered because the brittleness peculiar to the MgF₂ film is reduced by including the organic skeleton in the film, but the strength peculiar to the MgF₂ film is exhibited. Therefore, it is apparent that the effect of improving the wear resistance of the multilayer film is expected by adopting the MO mixed layer in the present invention as a surface layer in the multilayer film.

Next, an example of a multilayer film including the MO mixed layer in the present invention will be described.

### Fifth Example

The optical thin film 5 has eight layers and is manufactured as follows. First, a film of siloxane is formed by CVD, and a layer of organic SiO₂ is prepared as a first layer on the substrate. A PVD layer of silicon oxide is then made on the first layer as a second layer. Next, a PVD layer of titanium oxide is prepared as a third layer on the second layer. Then, the preparation of the PVD layer of silicon oxide and the PVD layer of titanium oxide is further repeated twice to prepare the fourth layer to the seventh layer. Subsequently, an MO mixed layer of magnesium fluoride and organic SiO₂ is prepared as an eighth layer on the seventh layer at a flow rate of siloxane gas of 30 sccm.

### Sixth Example

The optical thin film 6 has eight layers and is manufactured as follows. First, a film of siloxane is formed by CVD, and a layer of organic SiO₂ is prepared as a first layer on the substrate. A PVD layer of silicon oxide is then made on the first layer as a second layer. Next, a DO mixed layer of titanium oxide and organic SiO₂ is prepared as a third layer on the second layer. Subsequently, the preparation of the PVD layer of silicon oxide and the DO mixed layer of titanium oxide and organic SiO₂ is further repeated twice to prepare the fourth layer to the seventh layer. Subsequently, an MO mixed layer of magnesium fluoride and organic SiO₂ is prepared as an eighth layer on the seventh layer at a flow rate of siloxane gas of 10 sccm.

### Seventh Example

The optical thin film 7 has twelve layers and is manufactured as follows. First, a film of siloxane is formed by CVD, and a layer of organic SiO₂ is prepared as a first layer on the substrate. Then, the preparation of the PVD layer of silicon oxide and the PVD layer of titanium oxide is repeated five times to prepare the second layer to the eleventh layer. Subsequently, an MO mixed layer of magnesium fluoride and organic SiO₂ is prepared as a twelfth layer on the eleventh layer at a flow rate of siloxane gas of 30 sccm.

### Eighth Example

The optical thin film 8 has twelve layers and is manufactured as follows. First, a film of siloxane is formed by CVD, and a layer of organic SiO₂ is prepared as a first layer on the substrate. Subsequently, the preparation of the PVD layer of silicon oxide and the DO mixed layer of titanium oxide and organic SiO₂ is repeated five times to prepare the second layer to the eleventh layer. Subsequently, an MO mixed layer of magnesium fluoride and organic SiO₂ is prepared as a twelfth layer on the eleventh layer at a flow rate of siloxane gas of 30 sccm.

### Ninth Example

The optical thin film 9 has six layers and is manufactured as follows. First, the preparation of the PVD layer of silicon oxide and the DO mixed layer of titanium oxide and organic SiO₂ is repeated twice to prepare the first layer to the fourth layer on the substrate. Subsequently, an MO mixed layer of magnesium fluoride and organic SiO₂ is prepared as a fifth layer on the fourth layer at a flow rate of siloxane gas of 10 sccm. A PVD layer of silicon oxide is then made on the fifth layer as a sixth layer.

### Tenth Example

The optical thin film 10 has six layers and is manufactured as follows. First, a film of siloxane is formed by CVD, and a layer of organic SiO₂ is prepared as a first layer on the substrate. A PVD layer of a mixed compound of silicon oxide and aluminum oxide is then made on the first layer as the second layer. Next, a DO mixed layer of titanium oxide and organic SiO₂ is prepared as a third layer on the second layer. Next, the preparation of the PVD layer of the mixed compound of silicon oxide and aluminum oxide and the DO mixed layer of titanium oxide and organic SiO₂ is repeated one more time to prepare a fourth layer and a fifth layer. Subsequently, an MO mixed layer of magnesium fluoride and organic SiO₂ is prepared as a sixth layer on the fifth layer at a flow rate of siloxane gas of 30 sccm.

### Eleventh Example

The optical thin film 11 has eight layers and is manufactured as follows. First, a film of siloxane is formed by CVD, and a layer of organic SiO₂ is prepared as a first layer on the substrate. A PVD layer of a mixed compound of silicon oxide and aluminum oxide is then made on the first layer as the second layer. Next, a PVD layer of a mixed compound of titanium oxide and niobium oxide is prepared as a third layer on the second layer. Then, the preparation of the PVD layer of the mixed compound of silicon oxide and aluminum oxide and the PVD layer of the mixed compound of titanium oxide and niobium oxide is further repeated twice to prepare the fourth layer to the seventh layer. Subsequently, an MO mixed layer of magnesium fluoride and organic SiO₂ is prepared as an eighth layer on the seventh layer at a flow rate of siloxane gas of 10 sccm.

### Twelfth Example

The optical thin film 12 has seven layers and is manufactured as follows. The preparation of a PVD layer of a mixed compound of silicon oxide and aluminum oxide and a PVD layer of titanium oxide is repeated three times, and the first layer to the sixth layer are prepared on the substrate. Subsequently, an MO mixed layer of magnesium fluoride and organic SiO₂ is prepared as a seventh layer on the sixth layer at a flow rate of siloxane gas of 10 sccm.

### Thirteenth Example

The optical thin film 13 has eight layers and is manufactured as follows. First, a film of siloxane is formed by CVD, and a layer of organic SiO₂ is prepared as a first layer on the substrate. A PVD layer of silicon oxide is then made on the first layer as a second layer. Next, a DO mixed layer of titanium oxide and organic SiO₂ is prepared as a third layer on the second layer. Subsequently, an MO mixed layer of magnesium fluoride and organic SiO₂ is prepared as a fourth layer on the third layer at a flow rate of siloxane gas of 30 sccm. Next, the preparation of the DO mixed layer of titanium oxide and organic SiO₂ and the MO mixed layer of magnesium fluoride and organic SiO₂ is further repeated twice to prepare the fifth layer to the eighth layer.

### Fourteenth Example

The optical thin film 14 has ten layers and is manufactured as follows. First, a film of siloxane is formed by CVD, and a layer of organic SiO₂ is prepared as a first layer on the substrate. A PVD layer of a mixed compound of silicon oxide and aluminum oxide is then made on the first layer as the second layer. Next, a PVD layer of titanium oxide is prepared as a third layer on the second layer. Subsequently, the preparation of a PVD layer of a mixed compound of silicon oxide and aluminum oxide and a PVD layer of titanium oxide is repeated three times, and the fourth layer to the ninth layer are prepared on the substrate. Subsequently, an MO mixed layer of magnesium fluoride and organic SiO₂ is prepared as a tenth layer on the ninth layer at a flow rate of siloxane gas of 30 sccm.

### Second Comparative Example

The optical thin film C2 is configured similarly to the optical thin film 3 except that the eighth layer is a layer made of magnesium fluoride. The optical thin film C2 is prepared by the same method as the optical thin film 3 described above except that a PVD layer of magnesium fluoride is prepared on the seventh layer as the eighth layer.

### Third Comparative Example

The optical thin film C3 has eight layers and is manufactured as follows. First, a film of siloxane is formed by CVD, and a layer of organic SiO₂ is prepared as a first layer on the substrate. Subsequently, the preparation of a PVD layer of a mixed compound of silicon oxide and aluminum oxide and a PVD layer of titanium oxide is repeated three times, and the second layer to the seventh layer are prepared. Next, a PVD layer of magnesium fluoride is prepared as an eighth layer on the seventh layer.

### Fourth Comparative Example

The optical thin film C4 has eight layers and is manufactured as follows. First, a film of siloxane is formed by CVD, and a layer of organic SiO₂ is prepared as a first layer on the substrate. A PVD layer of silicon oxide is then made on the first layer as a second layer. Next, a PVD layer of titanium oxide is prepared as a third layer on the second layer. Then, the preparation of the PVD layer of silicon oxide and the PVD layer of titanium oxide is further repeated twice to prepare the fourth layer to the seventh layer. A PVD layer of silicon oxide is then made on the seventh layer as an eighth layer.

The layer configuration and the entire film stress of the optical thin films 5 to 14 and C2 to C4, which are multilayer films, are shown in Tables 3 to 5.

TABLE 3

| Optical | | | | | |
|---|---|---|---|---|---|
| thin | | | | | |
| film No. | 5 | 6 | 7 | 8 | 9 |
| First | Organic | Organic | Organic | Organic | SiO₂ |
| layer | SiO₂ | SiO₂ | SiO₂ | SiO₂ | |
| Second | SiO₂ | SiO₂ | SiO₂ | SiO₂ | TiO₂ + |
| layer | | | | | Organic |
| | | | | | SiO₂ |
| Third | TiO₂ | TiO₂ + | TiO₂ | TiO₂ + | SiO₂ |
| layer | | Organic | | Organic | |
| | | SiO₂ | | SiO₂ | |
| Fourth | SiO₂ | SiO₂ | SiO₂ | SiO₂ | TiO₂ + |
| layer | | | | | Organic |
| | | | | | SiO₂ |
| Fifth | TiO₂ | TiO₂ + | TiO₂ | TiO₂ + | MgF₂ + |
| layer | | Organic | | Organic | Organic |
| | | SiO₂ | | SiO₂ | SiO₂ |
| Sixth | SiO₂ | SiO₂ | SiO₂ | SiO₂ | SiO₂ |
| layer | | | | | |
| Seventh | TiO₂ | TiO₂ + | TiO₂ | TiO₂ + | |
| layer | | Organic | | Organic | |
| | | SiO₂ | | SiO₂ | |
| Eighth | MgF₂ + | MgF₂ + | SiO₂ | SiO₂ | |
| layer | Organic | Organic | | | |
| | SiO₂ | SiO₂ | | | |
| Ninth | | | TiO₂ | TiO₂ + | |
| layer | | | | Organic | |
| | | | | SiO₂ | |
| Tenth | | | SiO₂ | SiO₂ | |
| layer | | | | | |
| Eleventh | | | TiO₂ | TiO₂ + | |
| layer | | | | Organic | |
| | | | | SiO₂ | |
| Twelfth | | | MgF₂ + | MgF₂ + | |
| layer | | | Organic | Organic | |
| | | | SiO₂ | SiO₂ | |
| Film | −150 | −199 | −235 | −300 | −196 |
| stress | | | | | |
| [Mpa] | | | | | |

TABLE 4

| Optical | | | | | |
|---|---|---|---|---|---|
| thin | | | | | |
| film No. | 10 | 11 | 12 | 13 | 14 |
| First | Organic | Organic | SiO₂ + | Organic | Organic |
| layer | SiO₂ | SiO₂ | Al₂O₃ | SiO₂ | SiO₂ |
| Second | SiO₂ + | SiO₂ + | TiO₂ | SiO₂ | SiO₂ + |
| layer | Al₂O₃ | Al₂O₃ | | | Al₂O₃ |
| Third | TiO₂ + | TiO₂ + | SiO₂ + | TiO₂ + | TiO₂ |
| layer | Organic | Nb₂O₅ | Al₂O₃ | Organic | |
| | SiO₂ | | | SiO₂ | |
| Fourth | SiO₂ + | SiO₂ + | TiO₂ | MgF₂ + | SiO₂ + |
| layer | Al₂O₃ | Al₂O₃ | | Organic | Al₂O₃ |
| | | | | SiO₂ | |
| Fifth | TiO₂ + | TiO₂ + | SiO₂ + | TiO₂ + | TiO₂ |
| layer | Organic | Nb₂O₅ | Al₂O₃ | Organic | |
| | SiO₂ | | | SiO₂ | |
| Sixth | MgF₂ + | SiO₂ + | TiO₂ | MgF₂ + | SiO₂ + |
| layer | Organic | Al₂O₃ | | Organic | Al₂O₃ |
| | SiO₂ | | | SiO₂ | |
| Seventh | | TiO₂ + | MgF₂ + | TiO₂ + | TiO₂ |
| layer | | Nb₂O₅ | Organic | Organic | |
| | | | SiO₂ | SiO₂ | |
| Eighth | | MgF₂ + | | MgF₂ + | SiO₂ + |
| layer | | Organic | | Organic | Al₂O₃ |
| | | SiO₂ | | SiO₂ | |
| Ninth | | | | | TiO₂ |
| layer | | | | | |
| Tenth | | | | | MgF₂ + |
| layer | | | | | Organic |
| | | | | | SiO₂ |
| Film | −371 | −286 | −208 | −202 | −338 |
| stress | | | | | |
| [Mpa] | | | | | |

TABLE 5

| Optical thin film | | | |
|---|---|---|---|
| No. | C2 | C3 | C4 |
| First layer | Organic SiO₂ | Organic SiO₂ | Organic SiO₂ |
| Second layer | SiO₂ | SiO₂ + Al₂O₃ | SiO₂ |
| Third layer | TiO₂ | TiO₂ | TiO₂ |
| Fourth layer | SiO₂ | SiO₂ + Al₂O₃ | SiO₂ |
| Fifth layer | TiO₂ | TiO₂ | TiO₂ |
| Sixth layer | SiO₂ | SiO₂ + Al₂O₃ | SiO₂ |
| Seventh layer | TiO₂ | TiO₂ | TiO₂ |
| Eighth layer | MgF₂ | MgF₂ | SiO₂ |
| Film stress [Mpa] | −70 | 136 | −218 |

### [Evaluation (Multilayer Film)]

### [Film Stress]

The overall film stress of the optical thin films 5 to 14 and C2 to C4 has been obtained as a calculated value obtained by adding the film stresses of the monolayer films of the respective layers. The values of the film stress of the monolayer film used for this calculation are shown in Table 6. The numerical values of the film stress described in Table 6 are values of the film stress per unit area (1 m₂).

TABLE 6

| | Film stress |
|---|---|
| Film property | [MPa] |
| Organic SiO₂ | −600 |
| TiO₂ | 200 |
| TiO₂ + Organic SiO₂ | −210 |
| TiO₂ + Nb₂O₅ | −120 |
| SiO₂ | −400 |
| SiO₂ + Al₂O₃ | −600 |
| MgF₂ | 400 |
| MgF₂ + Organic SiO₂ (10 sccm) | 200 |
| MgF₂ + Organic SiO₂ (30 sccm) | 50 |

### [Spectral Reflectance]

For each of the optical thin films 5 to 14 and C2 to C4, the spectral reflectance of the lens center portion on each surface of the resin lens has been measured using a microspectrometer USPM-RU-W manufactured by Olympus Corporation.

Then, in each optical thin film, the maximum value and the average value of the reflectance of light having a wavelength of 450 to 600 nm have been determined, and the allowable value of the reflectance of light having a wavelength of 450 to 600 nm has been set to less than 0.5%, which is considered to have no practical problem, and evaluation has been performed according to the following criteria. In each optical thin film, the maximum value and the average value of the reflectance have been also obtained for the reflectance of light having a wavelength of 400 to 850 nm, and the allowable value of the reflectance of light having a wavelength of 400 to 850 nm has been set to less than 1.58, which is considered to have no practical problem, and evaluation has been performed according to the following criteria.
∘: Both the maximum value and the average value are acceptable values.
Δ: One of the maximum value and the average value is an allowable value.
x: Both the maximum value and the average value exceed the allowable value.

### [Reliability Test]

### <High-Temperature Test and High-Temperature and High-Humidity Test>

A high-temperature test and a high-temperature and high-humidity test have been performed for each of the optical thin films 5 to 14 and C2 to C4. The high-temperature test is a test in which each optical thin film is allowed to stand for 500 hours in a thermostatic bath manufactured by ESPEC Corporation set at 110° C. The high-temperature and high-humidity test is a test in which each optical thin film is allowed to stand for 500 hours in a thermostatic bath set at 85° C. and a relative humidity of 85%. The surface of the optical thin film after each test has been observed with an optical microscope and evaluated according to the following criteria.
∘: No wrinkles or cracks are observed on the surface.
x: Wrinkles or cracks are observed on the surface.

### <Abrasion Test>

For each of the optical thin films 5 to 14 and C2 to C4, methanol has been impregnated into a wiper (Ozu-Sangyo Co., Ltd., Dusper K4), the optical thin film on the surface of the resin lens has been wiped back and forth 10 times with a load of about 200 g, and then the wiped surface has been visually observed, and evaluation was performed according to the following criteria.
⊙: No change is observed on the surface including scratches.
∘: No scratch is observed on the surface, and there is no problem in practical use.

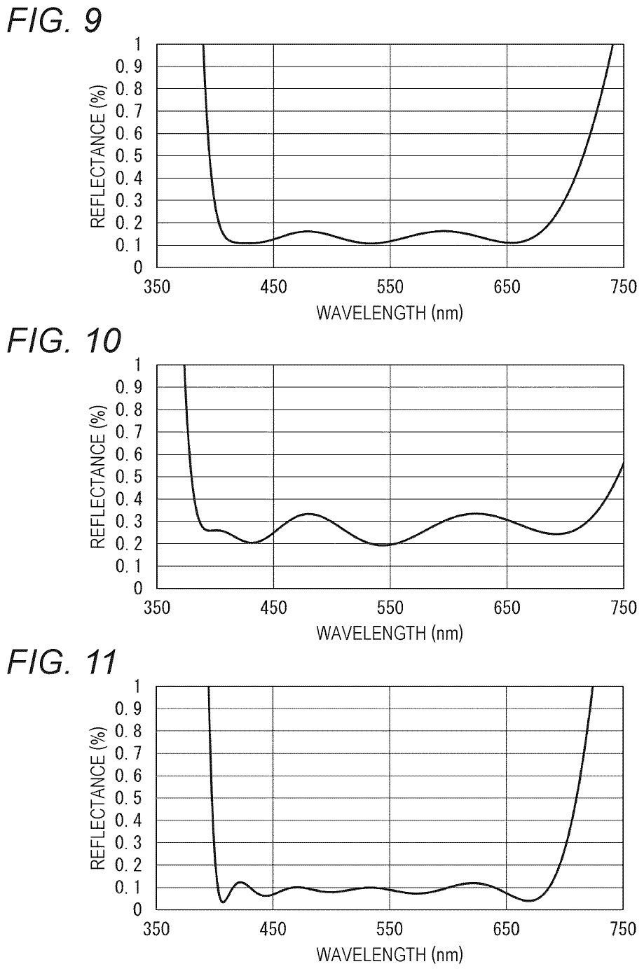

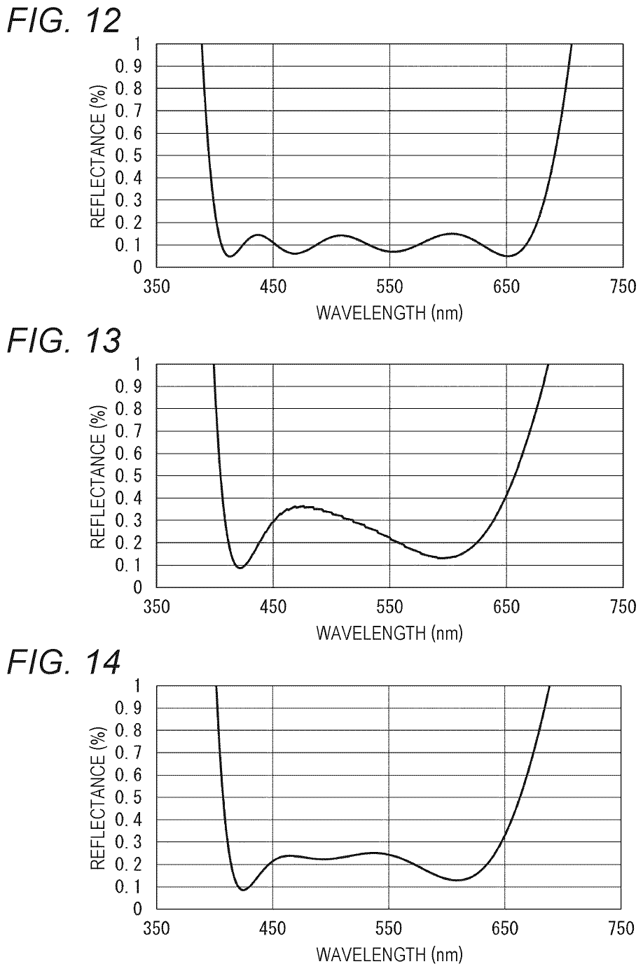

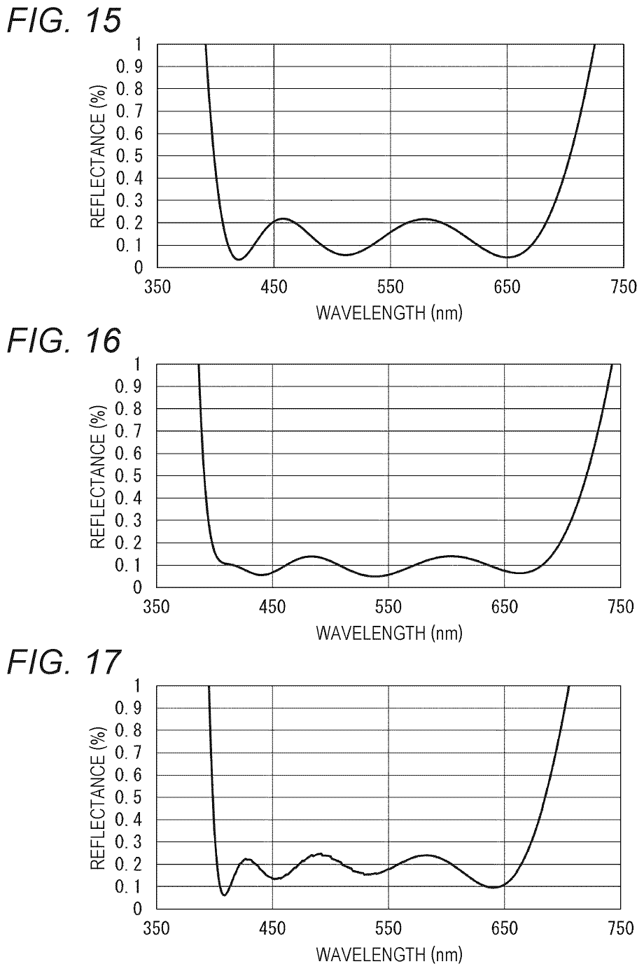

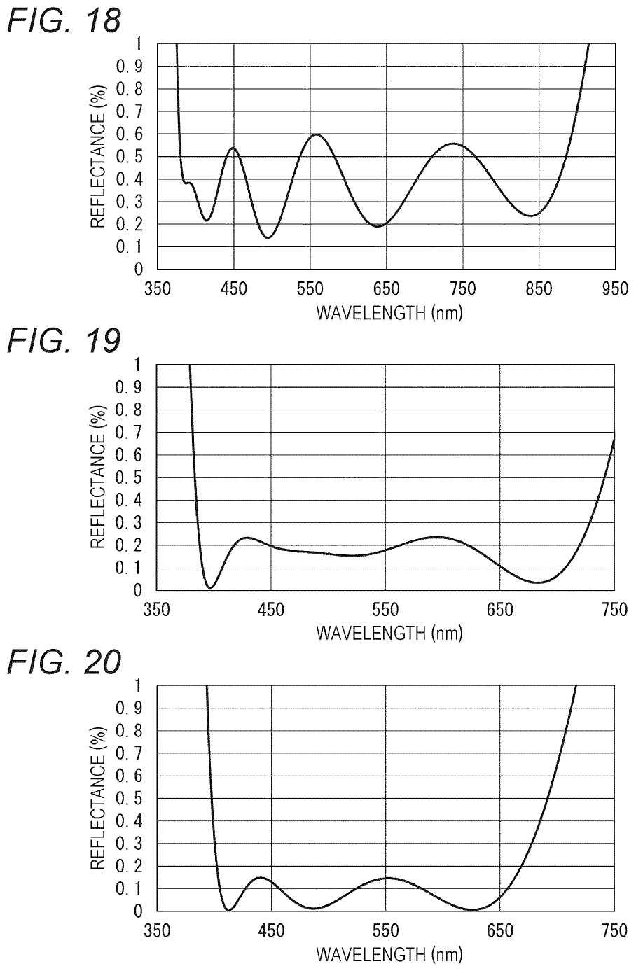

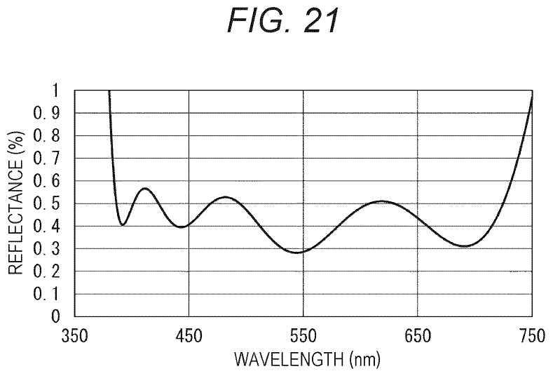

Table 7 shows the results of the film stress, spectral reflectance, high-temperature test, high-temperature and high-humidity test, and abrasion test for each of the optical thin films 5 to 14 and C2 to C4. For each of the optical thin films 5 to 14 and C2 to C4, the layer configuration, the film thickness of each layer, and the entire film stress are shown in Tables 8 to 20. FIGS. 9 to 21 show graphs of the reflectance of light having a wavelength of 350 to 750 nm for each of the optical thin films 5 to 14 and C2 to C4.

TABLE 7

| | | | | | | | | Reliability test | | |
|---|---|---|---|---|---|---|---|---|---|---|
| Optical | | Spectral reflectance [%] | | | | | | | High- | |
| thin | Film | 450 to 600 nm | | | 400 to 850 nm | | | | temperature | |
| film | stress | Maximum | Average | | Maximum | Average | | High- | and high- | |
| No. | [MPa] | value | value | Determination | value | value | Determination | temperature | humidity | Abrasion |
| 5 | −150 | 0.162 | 0.137 | ◯ | 5.472 | 0.874 | Δ | ◯ | ◯ | ◯ |
| 6 | −199 | 0.333 | 0.261 | ◯ | 3.120 | 0.583 | Δ | ◯ | ◯ | ◯ |
| 7 | −235 | 0.100 | 0.086 | ◯ | 13.770 | 1.928 | X | ◯ | ◯ | ◯ |
| 8 | −300 | 0.148 | 0.101 | ◯ | 13.022 | 2.199 | X | ◯ | ◯ | ◯ |
| 9 | −196 | 0.364 | 0.262 | ◯ | 6.026 | 1.431 | Δ | ◯ | ◯ | ⊙ |
| 10 | −371 | 0.250 | 0.220 | ◯ | 6.932 | 1.546 | X | ◯ | ◯ | ◯ |
| 11 | −286 | 0.218 | 0.150 | ◯ | 6.889 | 1.149 | Δ | ◯ | ◯ | ◯ |
| 12 | −208 | 0.139 | 0.097 | ◯ | 6.112 | 0.899 | Δ | ◯ | ◯ | ◯ |
| 13 | −202 | 0.247 | 0.199 | ◯ | 5.808 | 1.302 | Δ | ◯ | ◯ | ◯ |
| 14 | −338 | 0.598 | 0.399 | Δ | 0.598 | 0.373 | ◯ | ◯ | ◯ | ◯ |
| C2 | −70 | 0.235 | 0.182 | ◯ | 4.557 | 0.665 | Δ | X | ◯ | ◯ |
| C3 | 136 | 0.146 | 0.085 | ◯ | 5.821 | 1.058 | Δ | X | ◯ | ◯ |
| C4 | −218 | 0.527 | 0.404 | Δ | 5.704 | 1.012 | Δ | ◯ | ◯ | ⊙ |

TABLE 8

| Layer | Film property | Film thickness [nm] |
|---|---|---|
| First layer | Organic SiO₂ | 10.0 |
| Second layer | SiO₂ | 172.5 |
| Third layer | TiO₂ | 14.8 |
| Fourth layer | SiO₂ | 30.2 |
| Fifth layer | TiO₂ | 63.5 |
| Sixth layer | SiO₂ | 10.0 |
| Seventh layer | TiO₂ | 33.1 |
| Eighth layer | MgF₂ + Organic SiO₂ | 92.5 |

| | |
|---|---|
| Film stress [MPa] | −150 |

TABLE 9

| Layer | Film property | Film thickness [nm] |
|---|---|---|
| First layer | Organic SiO₂ | 10.0 |
| Second layer | SiO₂ | 173.6 |
| Third layer | TiO₂ + Organic SiO₂ | 16.7 |
| Fourth layer | SiO₂ | 29.6 |
| Fifth layer | TiO₂ + Organic SiO₂ | 75.3 |
| Sixth layer | SiO₂ | 9.3 |
| Seventh layer | TiO₂ + Organic SiO₂ | 34.8 |
| Eighth layer | MgF₂ + Organic SiO₂ | 92.6 |

| | |
|---|---|
| Film stress [MPa] | −199 |

TABLE 10

| Layer | Film property | Film thickness [nm] |
|---|---|---|
| First layer | Organic SiO₂ | 10.0 |
| Second layer | SiO₂ | 174.5 |
| Third layer | TiO₂ | 14.6 |
| Fourth layer | SiO₂ | 29.5 |
| Fifth layer | TiO₂ | 125.5 |
| Sixth layer | SiO₂ | 22.2 |
| Seventh layer | TiO₂ | 34.6 |
| Eighth layer | SiO₂ | 20.4 |
| Ninth layer | TiO₂ | 77.4 |
| Tenth layer | SiO₂ | 9.7 |
| Eleventh layer | TiO₂ | 28.6 |
| Twelfth layer | MgF₂ + Organic SiO₂ | 90.9 |

| | |
|---|---|
| Film stress [MPa] | −235 |

TABLE 11

| Layer | Film property | Film thickness [nm] |
|---|---|---|
| First layer | Organic SiO₂ | 10.0 |
| Second layer | SiO₂ | 174.4 |
| Third layer | TiO₂ + Organic SiO₂ | 11.6 |
| Fourth layer | SiO₂ | 53.0 |
| Fifth layer | TiO₂ + Organic SiO₂ | 16.5 |
| Sixth layer | SiO₂ | 184.6 |
| Seventh layer | TiO₂ + Organic SiO₂ | 10.0 |
| Eighth layer | SiO₂ | 10.0 |
| Ninth layer | TiO₂ + Organic SiO₂ | 36.2 |
| Tenth layer | SiO₂ | 10.0 |
| Eleventh layer | TiO₂ + Organic SiO₂ | 52.6 |
| Twelfth layer | MgF₂ + Organic SiO₂ | 90.4 |

| | |
|---|---|
| Film stress [MPa] | −300 |

TABLE 12

| Layer | Film property | Film thickness [nm] |
|---|---|---|
| First layer | SiO₂ | 183.1 |
| Second layer | TiO₂ + Organic SiO₂ | 24.7 |
| Third layer | SiO₂ | 36.3 |
| Fourth layer | TiO₂ + Organic SiO₂ | 36.7 |
| Fifth layer | MgF₂ + Organic SiO₂ | 100.8 |
| Sixth layer | SiO₂ | 10.0 |

| | |
|---|---|
| Film stress [MPa] | −196 |

TABLE 13

| Layer | Film property | Film thickness [nm] |
|---|---|---|
| First layer | Organic SiO₂ | 10.0 |
| Second layer | SiO₂ + Al₂O₃ | 183.7 |
| Third layer | TiO₂ + Organic SiO₂ | 25.3 |
| Fourth layer | SiO₂ + Al₂O₃ | 34.8 |
| Fifth layer | TiO₂ + Organic SiO₂ | 38.9 |
| Sixth layer | MgF₂ + Organic SiO₂ | 99.8 |

| | |
|---|---|
| Film stress [MPa] | −371 |

TABLE 14

| Layer | Film property | Film thickness [nm] |
|---|---|---|
| First layer | Organic SiO₂ | 10.0 |
| Second layer | SiO₂ + Al₂O₃ | 147.8 |
| Third layer | TiO₂ + Nb₂O₅ | 11.0 |
| Fourth layer | SiO₂ + Al₂O₃ | 34.1 |
| Fifth layer | TiO₂ + Nb₂O₅ | 54.4 |
| Sixth layer | SiO₂ + Al₂O₃ | 10.0 |
| Seventh layer | TiO₂ + Nb₂O₅ | 45.0 |
| Eighth layer | MgF₂ + Organic SiO₂ | 93.2 |

| | |
|---|---|
| Film stress [MPa] | −286 |

TABLE 15

| Layer | Film property | Film thickness [nm] |
|---|---|---|
| First layer | SiO₂ + Al₂O₃ | 173.5 |
| Second layer | TiO₂ | 14.8 |
| Third layer | SiO₂ + Al₂O₃ | 29.2 |
| Fourth layer | TiO₂ | 66.1 |
| Fifth layer | SiO₂ + Al₂O₃ | 10.0 |
| Sixth layer | TiO₂ | 30.5 |
| Seventh layer | MgF₂ + Organic SiO₂ | 92.7 |

| | |
|---|---|
| Film stress [MPa] | −208 |

TABLE 16

| Layer | Film property | Film thickness [nm] |
|---|---|---|
| First layer | Organic SiO₂ | 10.0 |
| Second layer | SiO₂ | 209.6 |
| Third layer | TiO₂ + Organic SiO₂ | 14.0 |
| Fourth layer | MgF₂ + Organic SiO₂ | 59.5 |
| Fifth layer | TiO₂ + Organic SiO₂ | 28.7 |
| Sixth layer | MgF₂ + Organic SiO₂ | 36.2 |
| Seventh layer | TiO₂ + Organic SiO₂ | 138.0 |
| Eighth layer | MgF₂ + Organic SiO₂ | 89.8 |

| | |
|---|---|
| Film stress [MPa] | −202 |

TABLE 17

| Layer | Film property | Film thickness [nm] |
|---|---|---|
| First layer | Organic SiO₂ | 10.0 |
| Second layer | SiO₂ + Al₂O₃ | 187.8 |
| Third layer | TiO₂ | 10.3 |
| Fourth layer | SiO₂ + Al₂O₃ | 42.1 |
| Fifth layer | TiO₂ | 30.2 |
| Sixth layer | SiO₂ + Al₂O₃ | 13.5 |
| Seventh layer | TiO₂ | 74.6 |
| Eighth layer | SiO₂ + Al₂O₃ | 17.9 |
| Ninth layer | TiO₂ | 23.8 |
| Tenth layer | MgF₂ + Organic SiO₂ | 99.4 |

| | |
|---|---|
| Film stress [MPa] | −338 |

TABLE 18

| Layer | Film property | Film thickness [nm] |
|---|---|---|
| First layer | Organic SiO₂ | 10.0 |
| Second layer | SiO₂ | 171.1 |
| Third layer | TiO₂ | 14.8 |
| Fourth layer | SiO₂ | 27.1 |
| Fifth layer | TiO₂ | 92.6 |
| Sixth layer | SiO₂ | 12.6 |
| Seventh layer | TiO₂ | 16.8 |
| Eighth layer | MgF₂ | 87.8 |

| | |
|---|---|
| Film stress [MPa] | −70 |

TABLE 19

| Layer | Film property | Film thickness [nm] |
|---|---|---|
| First layer | Organic SiO₂ | 10.0 |
| Second layer | SiO₂ + Al₂O₃ | 10.0 |
| Third layer | TiO₂ | 16.7 |
| Fourth layer | SiO₂ + Al₂O₃ | 27.3 |
| Fifth layer | TiO₂ | 70.8 |
| Sixth layer | SiO₂ + Al₂O₃ | 10.0 |
| Seventh layer | TiO₂ | 30.0 |
| Eighth layer | MgF₂ | 93.7 |

| | |
|---|---|
| Film stress [MPa] | 136 |

TABLE 20

| Layer | Film property | Film thickness [nm] |
|---|---|---|
| First layer | Organic SiO₂ | 10.0 |
| Second layer | SiO₂ | 10.0 |
| Third layer | TiO₂ | 16.7 |
| Fourth layer | SiO₂ | 27.3 |
| Fifth layer | TiO₂ | 70.8 |
| Sixth layer | SiO₂ | 10.0 |
| Seventh layer | TiO₂ | 30.0 |
| Eighth layer | SiO₂ | 93.7 |

| | |
|---|---|
| Film stress [MPa] | −218 |

### [Consideration (Multilayer Film)]

As is clear from the above description, the optical thin films 5 to 14 have a high degree of freedom in design. Therefore, it is clear that the optical thin film of the multilayer film of the present invention can constitute various multilayer films having various layer configurations by changing the number of layers and the film substance to be used.

In addition, in the optical thin films 5 to 14, neither cracks nor wrinkles have been generated in both the high-temperature test and the high-temperature and high-humidity test. In addition, each of the optical thin films 5 to 13 exhibits a low reflectance of less than 0.5% at a wavelength of 450 to 600 nm. Among them, the optical thin films 5, 6, 9, and 11 to 13 exhibit a low reflectance in which the average value is less than 1.5% even at a wavelength of 400 to 850 nm. Furthermore, the optical thin film 14 exhibits a low reflectance in which the maximum value exceeds 0.5% at a wavelength of 450 to 600 nm, but both the maximum value and the average value are less than 1.5% at a wavelength of 400 to 850 nm.

From the above results, it is found that it is possible to prepare a coating for plastic lens having low reflection and high temperature reliability by using an MgF₂ film prepared by PVD+CVD mixed film formation for a multilayer film.

On the other hand, cracks have been generated in both the optical thin films C2 and C3 in the high-temperature test. According to this result, it can be assumed that the crack generation threshold is between 70 MPa as the compressive stress and 150 MPa (−70 to 150 MPa) as the tensile stress. In addition, according to the above results, in the optical thin films 5 to 14 according to the examples of the present invention, since the layer of MgF₂ is replaced with the MO mixed film of MgF₂ and an organosilicon compound, the compressive stress of the entire multilayer film is increased, leading to suppression of cracks. The film stress of the multilayer film in the examples of the present invention can be adjusted to a desired film stress by changing the mixing ratio of the precursor gas.

In the optical thin film C4, the maximum value exceeds the allowable value for both the spectral reflectances at the wavelength of 450 to 600 nm and the wavelength of 400 to 850 nm. As described above, when the reliability is increased in the conventional optical thin film, the antireflection performance is reduced (the reliability and the antireflection performance are in a trade-off relationship).

The present invention is expected to be applicable to all technical fields in which a substrate having relatively large thermal expansion and contraction is coated with a thin film having relatively small thermal expansion and contraction, and is expected to contribute to further development of the technical field.

What is claimed is:

1. An optical thin film comprising one or more MO mixed layers in which an organometallic compound is mixed in a layer formed by physical vapor deposition of magnesium fluoride.

2. The optical thin film according to claim 1, wherein the optical thin film is a multilayer film formed by stacking two or more dielectric layers having different refractive indexes, and includes the MO mixed layer as at least one layer of the dielectric layers.

3. The optical thin film according to claim 2, wherein the dielectric layer is a layer of an oxide, an oxynitride, or a nitride of a dielectric material containing one or more elements selected from a group consisting of Ti, Zr, Ta, La, Nb, Hf, Al, Si, Pr, Y, and Ce, the dielectric material being formed by physical vapor deposition.

4. The optical thin film according to claim 2, wherein the dielectric layer includes a DO mixed layer in which an organometallic compound is mixed in a layer of an oxide, an oxynitride, or a nitride of a dielectric material containing one or more elements selected from a group consisting of Ti, Zr, Ta, La, Nb, Hf, Al, Si, Pr, Y, and Ce, the dielectric material being formed by physical vapor deposition.

5. The optical thin film according to claim 1, wherein the organometallic compound is an organic compound containing one or more elements selected from a group consisting of Si, Al, Ti, Hf, and Mg.

6. The optical thin film according to claim 1, comprising the MO mixed layer as an optical outermost layer.

7. The optical thin film according to claim 1, wherein the optical thin film has a film stress of +200 to −1000 MPa when a tensile stress is positive and a compressive stress is negative.

8. The optical thin film according to claim 1, wherein a reflectance of light having a wavelength of 450 to 600 nm is 0.5% or less, or a reflectance of light having a wavelength of 400 to 850 nm is 1.5% or less.

9. An optical element comprising:
a substrate; and
the optical thin film according to claim 1 supported on the substrate.

10. The optical element according to claim 9, further comprising an adhesion layer interposed between the substrate and the optical thin film.

11. The optical element according to claim 9, further comprising a protective film having a film thickness of 50 nm or less on a surface of the optical thin film.

12. The optical element according to claim 9, wherein the substrate is made of a plastic resin.

13. An optical apparatus comprising the optical element according to claim 9.

14. A manufacturing method of an optical thin film, comprising forming a layer of a dielectric material on a substrate by physical vapor deposition in an atmosphere containing an organometallic compound and a reactive gas to form a mixed layer in which the organometallic compound is mixed in the layer of an oxide, an oxynitride, or a nitride of the dielectric material,
wherein the forming of the mixed layer includes forming an MO mixed layer in which the organometallic compound is mixed in a layer by physical vapor deposition of magnesium fluoride using magnesium fluoride as the dielectric material.
